(19) United States
(12) Patent Application Publication
(10) Pub. No.: US 2025/0336907 A1
(43) Pub. Date: Oct. 30, 2025

(54) FIELD PROGRAMMABLE MULTICHIP PACKAGE COMPRISING FPGA IC CHIP AND NVM IC CHIP

(71) Applicant: iCometrue Company Ltd., Zhubei City (TW)

(72) Inventors: Mou-Shiung Lin, Hsinchu City (TW); Jin-Yuan Lee, Miaoli County (TW); Ping-Jung Yang, HsinChu City (TW)

(21) Appl. No.: 19/186,637

(22) Filed: Apr. 23, 2025

Related U.S. Application Data
(60) Provisional application No. 63/638,934, filed on Apr. 25, 2024.

(51) Int. Cl. H01L 25/18; H01L 23/00; H01L 23/495; H01L 23/498; H01L 23/528; H01L 23/538; H10B 80/00; H10D 80/30

(52) U.S. Cl. CPC H01L 25/18; H01L 23/49816; H01L 23/528; H01L 23/5385; H01L 24/05; H01L 24/13; H01L 24/16; H01L 24/48; H01L 24/73; H10B 80/00; H10D 80/30; H01L 23/49555; H01L 23/5386; H01L 24/32; H01L 2224/05147; H01L 2224/05624; H01L 2224/13083; H01L 2224/13147; H01L 2224/13611; H01L 2224/16147; H01L 2224/16227; H01L 2224/32145; H01L 2224/32225; H01L 2224/32245; H01L 2224/48091; H01L 2224/48145; H01L 2224/48227; H01L 2224/48247; H01L 2224/48465; H01L 2224/73204; H01L 2224/73215; H01L 2224/73253; H01L 2224/73265; H01L 2225/06506; H01L 2225/0651; H01L 2225/06513; H01L 2225/06517; H01L 2225/06524; H01L 2225/06562; H01L 2924/1431; H01L 2924/1438

(57) ABSTRACT

A chip package includes a ball-grid-array (BGA) substrate; a first metal bump at a bottom of the ball-grid-array (BGA) substrate, wherein the first metal bump comprises tin; a field programmable chip package over and coupling to the ball-grid-array (BGA) substrate, wherein the field programmable chip package comprises a field-programmable-gate-array (FPGA) integrated-circuit (IC) chip therein and a second metal bump at a bottom of the field programmable chip package and bonded to a top of the ball-grid-array (BGA) substrate; and a memory chip package under and coupling to the ball-grid-array (BGA) substrate, wherein the memory chip package comprises a first non-volatile memory (NVM) integrated-circuit (IC) chip therein and a third metal bump at a top of the memory chip package and bonded to the bottom of the ball-grid-array (BGA) substrate.

### PRIORITY CLAIM

This application claims priority benefits from U.S. provisional application No. 63/638,934, filed on Apr. 25, 2024 and entitled “Field Programmable Multichip Package Comprising FPGA IC Chip and NVM IC Chip”. The present application incorporates the foregoing disclosures herein by reference.

### FIELD OF THE DISCLOSURE

The present invention relates to a multichip package and, in particular, to a field programmable multichip package.

### BRIEF DESCRIPTION OF THE RELATED ART

The Field Programmable Gate Array (FPGA) semiconductor integrated circuit (IC) has been used for development of new or innovated applications, or for small volume applications or business demands. When an application or business demand expands to a certain volume and extend to a certain time period, the semiconductor IC suppliers may usually implement the application in an Application Specific IC (ASIC) chip, or a Customer-Owned Tooling (COT) IC chip. The switch from the FPGA design to the ASIC or COT design is because the current FPGA IC chip, for a given application and compared with an ASIC or COT chip, (1) has a larger semiconductor chip size, lower fabrication yield, and higher fabrication cost, (2) consumes more power, (3) gives lower performance. When the semiconductor technology notes or generations migrates, following the Moore's Law, to advanced notes or generations (for example below 30 nm or 20 nm), the Non-Recurring Engineering (NRE) cost for designing an ASIC or COT chip increases greatly (more than US $5M or even exceeding US $10M, US $20M, US $50M or US $100M). The cost of a photo mask set for an ASIC or COT chip at the 16 nm technology note or generation may be over US $2M, US $5M, or US $10M. The high NRE cost in implementing the innovation or application using the advanced IC technology notes or generations slows down or even stops the innovation or application using advanced and useful semiconductor technology notes or generations. A new approach or technology is needed to inspire the continuing innovation and to lower down the barrier for implementing the innovation in the semiconductor IC chips.

### SUMMARY OF THE DISCLOSURE

One aspect of the disclosure provides a chip package. The chip package may include a ball-grid-array (BGA) substrate; a first metal bump at a bottom of the ball-grid-array (BGA) substrate, wherein the first metal bump comprises tin; a field programmable chip package over and coupling to the ball-grid-array (BGA) substrate, wherein the field programmable chip package comprises a field-programmable-gate-array (FPGA) integrated-circuit (IC) chip therein and a second metal bump at a bottom of the field programmable chip package and bonded to a top of the ball-grid-array (BGA) substrate; and a memory chip package under and coupling to the ball-grid-array (BGA) substrate, wherein the memory chip package comprises a first non-volatile memory (NVM) integrated-circuit (IC) chip therein and a third metal bump at a top of the memory chip package and bonded to the bottom of the ball-grid-array (BGA) substrate.

In another aspect of the disclosure, the chip package further may further includes an interconnection substrate under the ball-grid-array (BGA) substrate and a fourth metal bump at a bottom of the interconnection substrate, wherein the first metal bump is bonded to a top of the interconnection substrate.

In another aspect of the disclosure, the memory chip package may have a portion in a hole vertically in the interconnection substrate.

These, as well as other components, steps, features, benefits, and advantages of the present application, will now become clear from a review of the following detailed description of illustrative embodiments, the accompanying drawings, and the claims.

### BRIEF DESCRIPTION OF THE DRAWINGS

The drawings disclose illustrative embodiments of the present application. They do not set forth all embodiments. Other embodiments may be used in addition or instead. Details that may be apparent or unnecessary may be omitted to save space or for more effective illustration. Conversely, some embodiments may be practiced without all of the details that are disclosed. When the same reference number or reference indicator appears in different drawings, it may refer to the same or like components or steps.

Aspects of the disclosure may be more fully understood from the following description when read together with the accompanying drawings, which are to be regarded as illustrative in nature, and not as limiting. The drawings are not necessarily to scale, emphasis instead being placed on the principles of the disclosure. In the drawings:

FIG. 1 is a cross-sectional view showing a first type of field-programmable multi-chip package for a first alternative in accordance with an embodiment of the present application.

FIG. 2 is a cross-sectional view showing a second type of field-programmable multi-chip package for a first alternative in accordance with an embodiment of the present application.

FIG. 3 is a cross-sectional view showing a third type of field-programmable multi-chip package in accordance with an embodiment of the present application.

FIG. 4 is a cross-sectional view showing a fourth type of multi-chip package in accordance with an embodiment of the present application.

FIGS. 5A and 5B are cross-sectional views showing a fifth type of multi-chip package in accordance with an embodiment of the present application.

FIG. 6 is a cross-sectional view showing a sixth type of multi-chip package in accordance with an embodiment of the present application.

FIG. 7 is a cross-sectional view showing a seventh type of multi-chip package in accordance with an embodiment of the present application.

FIG. 8A is a schematic view showing a block diagram of a field-programmable or configurable logic cell or element or look-up table (LUT) in accordance with an embodiment of the present application.

FIG. 8B is a circuit diagram illustrating a field-programmable or configurable switch in accordance with an embodiment of the present application.

FIG. 8C is a circuit diagram illustrating a field-programmable or configurable selection circuit in accordance with an embodiment of the present application.

FIG. 9A is a circuit diagram illustrating a multiplexer used as the first selection circuit of the field-programmable or configurable look-up table (LUT) as seen in FIG. 8A in accordance with an embodiment of the present application.

FIG. 9B is a circuit diagram illustrating the pass/no-pass switch of the field-programmable or configurable switch as seen in FIG. 8B in accordance with an embodiment of the present application.

FIG. 9C is a circuit diagram illustrating a multiplexer used as the second selection circuit of the field-programmable or configurable selection circuit as seen in FIG. 8C in accordance with an embodiment of the present application.

While certain embodiments are depicted in the drawings, one skilled in the art will appreciate that the embodiments depicted are illustrative and that variations of those shown, as well as other embodiments described herein, may be envisioned and practiced within the scope of the present application.

### DETAILED DESCRIPTION OF THE DISCLOSURE

Illustrative embodiments are now described. Other embodiments may be used in addition or instead. Details that may be apparent or unnecessary may be omitted to save space or for a more effective presentation. Conversely, some embodiments may be practiced without all of the details that are disclosed.

### Specification for First Type of Field-Programmable Multi-Chip Package

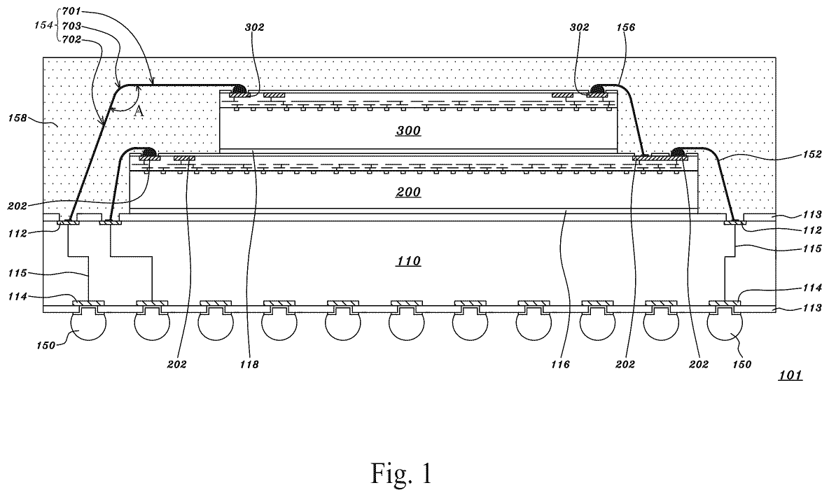

FIG. 1 is a cross-sectional view showing a first type of field-programmable multi-chip package for a first alternative in accordance with an embodiment of the present application. Referring to FIG. 1, a first type of field-programmable multi-chip package 101 for a first alternative may comprise (1) an interconnection substrate 110, e.g., ball-grid-array (BGA) substrate, including multiple bonding pads 112 at a top of its interconnection substrate 110 and multiple bonding pads 114 at a bottom of its interconnection substrate 110 opposite to the top of its interconnection substrate 110, wherein each of the bonding pads 112 of its interconnection substrate 110 may couple to one or more of the bonding pads 114 of its interconnection substrate 110 via an internal interconnect 115 of its interconnection substrate 110, (2) multiple metal bumps 150, such as solder bumps, in an array each having a top end bonded to one of the bonding pads 114 of its interconnection substrate 110 to act as its external pin for coupling to an external circuit outside of the first type of field-programmable multi-chip package 101 for the first alternative, wherein each of its metal bumps 150 may be made of a lead-free solder containing tin, copper, silver, bismuth, indium, zinc, antimony and/or traces of other metals, e.g., Sn—Ag—Cu (SAC) solder, Sn—Ag solder or Sn—Ag—Cu—Zn solder, (3) a bottom semiconductor integrated-circuit (IC) chip 200, which is a field-programmable-gate-array (FPGA) integrated-circuit (IC) chip for the first alternative, having a backside bonded to the top of its interconnection substrate 110 via an adhesive or glue layer 116, wherein its field-programmable-gate-array (FPGA) integrated-circuit (IC) chip 200 may include multiple bonding pads 202, made of a copper or aluminum layer having a thickness between 0.1 and 2 micrometers for example, at an active side of its field-programmable-gate-array (FPGA) integrated-circuit (IC) chip 200 opposite to the backside of its field-programmable-gate-array (FPGA) integrated-circuit (IC) chip 200, (4) a top semiconductor integrated-circuit (IC) chip 300, which is a non-volatile memory (NVM) integrated-circuit (IC) chip for the first alternative, such as NAND or NOR flash integrated-circuit (IC) chip, magnetoresistive random-access memory (MRAM) integrated-circuit (IC) chip, resistive random-access memory (RRAM) integrated-circuit (IC) chip or ferroelectric random-access memory (FRAM) integrated-circuit (IC) chip, having a backside bonded to the active side of its field-programmable-gate-array (FPGA) integrated-circuit (IC) chip 200 via an adhesive or glue layer 118, wherein its non-volatile memory (NVM) integrated-circuit (IC) chip 300 may include multiple bonding pads 302, made of a copper or aluminum layer having a thickness between 0.1 and 2 micrometers for example, at an active side of its non-volatile memory (NVM) integrated-circuit (IC) chip 300 opposite to the backside of its non-volatile memory (NVM) integrated-circuit (IC) chip 300, (5) multiple first wirebonded wires 152, made of gold or copper, each having a first end bonded onto one of the bonding pads 202 of its field-programmable-gate-array (FPGA) integrated-circuit (IC) chip 200 and a second end bonded onto one of the bonding pads 112 of its interconnection substrate 110 to couple its field-programmable-gate-array (FPGA) integrated-circuit (IC) chip 200 to its interconnection substrate 110, (6) multiple second wirebonded wires 154, made of gold or copper, each having a first end bonded onto one of the bonding pads 302 of its non-volatile memory (NVM) integrated-circuit (IC) chip 300 and a second end bonded onto one of the bonding pads 112 of its interconnection substrate 110 to couple its non-volatile memory (NVM) integrated-circuit (IC) chip 300 to its interconnection substrate 110, (7) multiple third wirebonded wires 156, made of gold or copper, each having a first end bonded onto one of the bonding pads 302 of its non-volatile memory (NVM) integrated-circuit (IC) chip 300 and a second end bonded onto one of the bonding pads 202 of its field-programmable-gate-array (FPGA) integrated-circuit (IC) chip 200 to couple its non-volatile memory (NVM) integrated-circuit (IC) chip 300 to its field-programmable-gate-array (FPGA) integrated-circuit (IC) chip 200, and (8) a molding compound 158 or sealing layer, such as epoxy, on the top of its interconnection substrate 110 and encapsulating its field-programmable-gate-array (FPGA) integrated-circuit (IC) chip 200 and non-volatile memory (NVM) integrated-circuit (IC) chip 300 and each of its first, second and third wirebonded wires 152, 154 and 156, wherein its molding compound 158 may have a sidewall coplanar with, in a vertical direction, a sidewall of its interconnection substrate 110.

Referring to FIG. 1, for the first type of field-programmable multi-chip package 101 for the first alternative, in case that its interconnection substrate 110 is a ball-grid-array (BGA) substrate, its ball-grid-array (BGA) substrate 110 may include (1) a core layer, such as FR4, containing epoxy or bismaleimide-triazine (BT) resin and having a thickness between 200 and 1000 micrometers or between 400 and 800 micrometers, wherein FR4 may be a composite material composed of woven fiberglass cloth and an epoxy resin binder, for example, (2) multiple interconnection metal layers, made of copper, each having a thickness between 10 and 50 micrometers, between 25 and 50 micrometers, between 10 and 40 micrometers or between 10 and 20 micrometers and over or under the core layer of its ball-grid-array (BGA) substrate 110, wherein each of the interconnection metal layers of its ball-grid-array (BGA) substrate 110 over the core layer of its ball-grid-array (BGA) substrate 110 may couple to any of the interconnection metal layers of its ball-grid-array (BGA) substrate 110 under the core layer of its ball-grid-array (BGA) substrate 110 through a through hole in the core layer of its ball-grid-array (BGA) substrate 110, (3) multiple polymer layers, i.e., insulating dielectric layers, such as Ajinomoto build-up films (ABFs) or layers of bismaleimide-triazine (BT) resin, each having a thickness between 10 and 50 micrometers, between 15 and 40 micrometers or between 20 and 30 micrometers and over or under the core layer of its ball-grid-array (BGA) substrate 110 and between neighboring two of the interconnection metal layers of its ball-grid-array (BGA) substrate 110, wherein each of the Ajinomoto build-up films (ABFs) may be made of epoxy, phenol hardener, cyanate ester and thermosetting olefin, wherein each of the internal interconnects 115 of its ball-grid-array (BGA) substrate 110 may be provided by each of the interconnection metal layers of its ball-grid-array (BGA) substrate 110, and (4) two solder masks 113, each made of a polymer layer or an insulating dielectric layer having a thickness between 10 and 50 micrometers, between 15 and 40 micrometers or between 20 and 30 micrometers, at the top and bottom of its ball-grid-array (BGA) substrate 110 respectively to cover the topmost and bottommost ones of the interconnection metal layers of its ball-grid-array (BGA) substrate 110 respectively, wherein each of the bonding pads 112 of its ball-grid-array (BGA) substrate 110 may be provided by the topmost one of the interconnection metal layers of its ball-grid-array (BGA) substrate 110 and at a bottom of an opening in the top one of the two solder masks 113 of its ball-grid-array (BGA) substrate 110, and each of the openings in the top one of the two solder masks 113 of its ball-grid-array (BGA) substrate 110 may be vertically over one of the bonding pads 112 of its ball-grid-array (BGA) substrate 110, and wherein each of the bonding pads 114 of its ball-grid-array (BGA) substrate 110 may be provided by the bottommost one of the interconnection metal layers of its ball-grid-array (BGA) substrate 110 and at a top of an opening in the bottom one of the two solder masks 113 of its ball-grid-array (BGA) substrate 110, and each of the openings in the bottom one of the two solder masks 113 of its ball-grid-array (BGA) substrate 110 may be vertically under one of the bonding pads 114 of its ball-grid-array (BGA) substrate 110.

Referring to FIG. 1, for the first type of field-programmable multi-chip package 101 for the first alternative, its field-programmable-gate-array (FPGA) integrated-circuit (IC) chip 200 may couple to its non-volatile memory (NVM) integrated-circuit (IC) chip 300 for signal transmission through one of its third wirebonded wires 156; its field-programmable-gate-array (FPGA) integrated-circuit (IC) chip 200 may couple to one of its metal bumps 150 for delivery of a voltage of power supply or ground reference or for signal transmission through, in sequence, one of its first wirebonded wires 152, one of the bonding pads 112 of its interconnection substrate 110, one of the internal interconnects 115 of its interconnection substrate 110 and one of the bonding pads 114 of its interconnection substrate 110; its non-volatile memory (NVM) integrated-circuit (IC) chip 300 may couple to another of its metal bumps 150 for delivery of a voltage of power supply or ground reference or for signal transmission through, in sequence, one of its second wirebonded wires 154, another of the bonding pads 112 of its interconnection substrate 110, another of the internal interconnects 115 of its interconnection substrate 110 and another of the bonding pads 114 of its interconnection substrate 110.

Alternatively, referring to FIG. 1, the bottom semiconductor integrated-circuit (IC) chip 200 of the first type of field-programmable multi-chip package 101 for a second alternative may be a non-volatile memory (NVM) integrated-circuit (IC) chip, instead of the field-programmable-gate-array (FPGA) integrated-circuit (IC) chip as mentioned for the first type of field-programmable multi-chip package 101 for the first alternative, and the top semiconductor integrated-circuit (IC) chip 300 of the first type of field-programmable multi-chip package 101 for the second alternative may be a field-programmable-gate-array (FPGA) integrated-circuit (IC) chip, instead of the non-volatile memory (NVM) integrated-circuit (IC) chip as mentioned for the first type of field-programmable multi-chip package 101 for the first alternative. For the first type of field-programmable multi-chip package 101 for the second alternative, its non-volatile memory (NVM) integrated-circuit (IC) chip 200 may couple to its field-programmable-gate-array (FPGA) integrated-circuit (IC) chip 300 for signal transmission through one of its third wirebonded wires 156; its non-volatile memory (NVM) integrated-circuit (IC) chip 200 may couple to one of its metal bumps 150 for delivery of a voltage of power supply or ground reference or for signal transmission through, in sequence, one of its first wirebonded wires 152, one of the bonding pads 112 of its interconnection substrate 110, one of the internal interconnects 115 of its interconnection substrate 110 and one of the bonding pads 114 of its interconnection substrate 110; its field-programmable-gate-array (FPGA) integrated-circuit (IC) chip 300 may couple to another of its metal bumps 150 for delivery of a voltage of power supply or ground reference or for signal transmission through, in sequence, one of its second wirebonded wires 154, another of the bonding pads 112 of its interconnection substrate 110, another of the internal interconnects 115 of its interconnection substrate 110 and another of the bonding pads 114 of its interconnection substrate 110.

Referring to FIG. 1, for the first type of field-programmable multi-chip package 101 for either alternative of the first and second alternatives, each of its first, second and third wirebonded wires 152, 154 and 156 may be a low-profiled wirebonded wire having a diameter between 5 and 15 micrometers, wherein the low-profiled wirebonded wire may be compressed at the first end thereof and have a first longitudinal loop 701 extending horizontally from the first end thereof, a second longitudinal loop 702 extending to the second end thereof and a curved loop 703 extending and connecting from the first longitudinal loop 701 thereof to the second longitudinal loop 702 thereof, wherein an angle A between the first and second longitudinal loops 701 and 702 thereof may be between 105 and 120 degrees. A vertical height of each of its second and third wirebonded wires 154 and 156 from a top surface of its top semiconductor integrated-circuit (IC) chip 300 at the top thereof may be between 10 and 30 micrometers and its top semiconductor integrated-circuit (IC) chip 300 may have a thickness between 10 and 50 micrometers. A vertical height of each of its first wirebonded wires 152 from a top surface of its bottom semiconductor integrated-circuit (IC) chip 200 at the top thereof may be between 10 and 30 micrometers.

### Specification for Second Type of Field-Programmable Multi-Chip Package

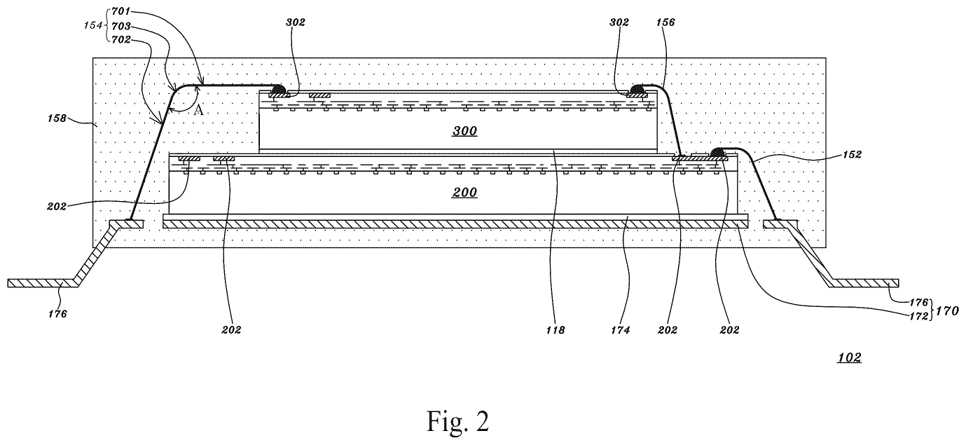

FIG. 2 is a cross-sectional view showing a second type of field-programmable multi-chip package for a first alternative in accordance with an embodiment of the present application. Referring to FIG. 2, a second type of field-programmable multi-chip package 102 for a first alternative may be provided with a similar structure to the first type of multi-chip package 101 for the first alternative as illustrated in FIG. 1. For an element indicated by the same reference number shown in FIGS. 1 and 2, the specification of the element as seen in FIG. 2 may be referred to that of the element as illustrated in FIG. 1. The difference therebetween is mentioned as below: the interconnection substrate 110 and metal bumps 150 of the first type of multi-chip package 101 for the first alternative may be replaced with a lead frame 170 for the second type of field-programmable multi-chip package 102 for the first alternative. For the second type of field-programmable multi-chip package 102 for the first alternative, its lead frame 170 may include (1) a chip pad 172, made of copper for example, having the backside of its field-programmable-gate-array (FPGA) integrated-circuit (IC) chip 200 bonded to a top of the chip pad 172 of its lead frame 170 via an adhesive or glue layer 174, and (2) multiple leads 176, made of copper for example, horizontally around and away from the chip pad 172 of its lead frame 170, wherein each of its first wirebonded wires 152, made of gold or copper, may have the first end bonded onto one of the bonding pads 202 of its field-programmable-gate-array (FPGA) integrated-circuit (IC) chip 200 and the second end bonded onto a first lead of the multiple leads 176 of its lead frame 170 to couple its field-programmable-gate-array (FPGA) integrated-circuit (IC) chip 200 to the first lead 176 of its lead frame 210, and each of its second wirebonded wires 154, made of gold or copper, may have the first end bonded onto one of the bonding pads 302 of its non-volatile memory (NVM) integrated-circuit (IC) chip 300 and the second end bonded onto a second lead of the multiple leads 176 of its lead frame 170 to couple its non-volatile memory (NVM) integrated-circuit (IC) chip 300 to the second lead 176 of its lead frame 170. Its molding compound 158 or sealing layer, such as epoxy, may be formed over the top of the chip pad 172 of its lead frame 170, on a bottom surface of the chip pad 172 of its lead frame 170 and in a horizontal gap between each neighboring two of the leads 176 of its lead frame 170 and cover an inner portion of each of the leads 176 of its lead frame 170 adjacent to the chip pad 172 of its lead frame 170. Each of the leads 176 of its lead frame 170 may include an outer portion not covered by its molding compound 158 to act as its external pin for coupling to an external circuit outside of the second type of field-programmable multi-chip package 102 for the first alternative. Its molding compound 158 may encapsulate its field-programmable-gate-array (FPGA) integrated-circuit (IC) chip 200 and non-volatile memory (NVM) integrated-circuit (IC) chip 300 and each of its first, second and third wirebonded wires 152, 154 and 156.

Referring to FIG. 2, for the second type of field-programmable multi-chip package 102 for the first alternative, its field-programmable-gate-array (FPGA) integrated-circuit (IC) chip 200 may couple to its non-volatile memory (NVM) integrated-circuit (IC) chip 300 for signal transmission through one of its third wirebonded wires 156; its field-programmable-gate-array (FPGA) integrated-circuit (IC) chip 200 may couple to one of the first leads 176 of its lead frame 170 for delivery of a voltage of power supply or ground reference or for signal transmission through one of its first wirebonded wires 152; its non-volatile memory (NVM) integrated-circuit (IC) chip 300 may couple to one of the second leads 176 of its lead frame 170 for delivery of a voltage of power supply or ground reference or for signal transmission through one of its second wirebonded wires 154.

Alternatively, referring to FIG. 2, the bottom semiconductor integrated-circuit (IC) chip 200 of the second type of field-programmable multi-chip package 102 for a second alternative may be a non-volatile memory (NVM) integrated-circuit (IC) chip, instead of the field-programmable-gate-array (FPGA) integrated-circuit (IC) chip as mentioned for the second type of field-programmable multi-chip package 102 for the first alternative, and the top semiconductor integrated-circuit (IC) chip 300 of the second type of field-programmable multi-chip package 102 for the second alternative may be a field-programmable-gate-array (FPGA) integrated-circuit (IC) chip, instead of the non-volatile memory (NVM) integrated-circuit (IC) chip as mentioned for the second type of field-programmable multi-chip package 102 for the first alternative. For the second type of field-programmable multi-chip package 102 for the second alternative, its non-volatile memory (NVM) integrated-circuit (IC) chip 200 may couple to its field-programmable-gate-array (FPGA) integrated-circuit (IC) chip 300 for signal transmission through one of its third wirebonded wires 156; its non-volatile memory (NVM) integrated-circuit (IC) chip 200 may couple to one of the first leads 176 of its lead frame 170 for delivery of a voltage of power supply or ground reference or for signal transmission through one of its first wirebonded wires 152; its field-programmable-gate-array (FPGA) integrated-circuit (IC) chip 300 may couple to one of the second leads 176 of its lead frame 170 for delivery of a voltage of power supply or ground reference or for signal transmission through one of its second wirebonded wires 154.

Referring to FIG. 2, for the second type of field-programmable multi-chip package 102 for either alternative of the first and second alternatives, each of its first, second and third wirebonded wires 152, 154 and 156 may be a low-profiled wirebonded wire having a diameter between 5 and 15 micrometers, wherein the low-profiled wirebonded wire may be compressed at the first end thereof and have a first longitudinal loop 701 extending horizontally from the first end thereof, a second longitudinal loop 702 extending to the second end thereof and a curved loop 703 extending and connecting from the first longitudinal loop 701 thereof to the second longitudinal loop 702 thereof, wherein an angle A between the first and second longitudinal loops 701 and 702 thereof may be between 105 and 120 degrees. A vertical height of each of its second and third wirebonded wires 154 and 156 from a top surface of its top semiconductor integrated-circuit (IC) chip 300 at the top thereof may be between 10 and 30 micrometers and its top semiconductor integrated-circuit (IC) chip 300 may have a thickness between 10 and 50 micrometers. A vertical height of each of its first wirebonded wires 152 from a top surface of its bottom semiconductor integrated-circuit (IC) chip 200 at the top thereof may be between 10 and 30 micrometers.

### Specification for Third Type of Field-Programmable Multi-Chip Package

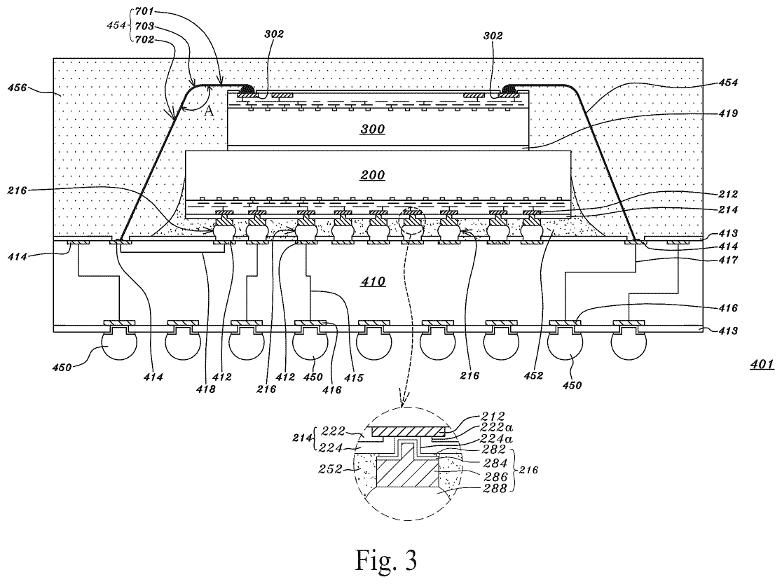

FIG. 3 is a cross-sectional view showing a third type of field-programmable multi-chip package in accordance with an embodiment of the present application. Referring to FIG. 3, a third type of field-programmable multi-chip package 401 may comprise (1) an interconnection substrate 410, e.g., ball-grid-array (BGA) substrate, including multiple first bonding pads 412 at a top of its interconnection substrate 410, multiple second bonding pads 414 at the top of its interconnection substrate 410 and horizontally surrounding the first bonding pads 412 of its interconnection substrate 410 and multiple third bonding pads 416 at a bottom of its interconnection substrate 410 opposite to the top of its interconnection substrate 410, wherein each of a first group of the first bonding pads 412 of its interconnection substrate 410 may couple to one or more of the third bonding pads 416 of its interconnection substrate 410 via a first internal interconnect 415 of its interconnection substrate 410, each of a first group of the second bonding pads 414 of its interconnection substrate 410 may couple to one or more of the third bonding pads 416 of its interconnection substrate 410 via a second internal interconnect 417 of its interconnection substrate 410, and each of a second group of the first bonding pads 412 of its interconnection substrate 410 may couple to one or more of a second group of the second bonding pads 414 of its interconnection substrate 410 via a third internal interconnect 418 of its interconnection substrate 410, (2) multiple metal bumps 450, such as solder bumps, in an array each having a top end bonded to one of the third bonding pads 416 of its interconnection substrate 410 to act as its external pin for coupling to an external circuit outside of the third type of field-programmable multi-chip package 401, wherein each of its metal bumps 450 may be made of a lead-free solder containing tin, copper, silver, bismuth, indium, zinc, antimony and/or traces of other metals, e.g., Sn—Ag—Cu (SAC) solder, Sn—Ag solder or Sn—Ag—Cu—Zn solder, (3) a field-programmable-gate-array (FPGA) integrated-circuit (IC) chip 200 having multiple bonding pads 212, made of a copper or aluminum layer having a thickness between 0.1 and 2 micrometers for example, at an active side of its field-programmable-gate-array (FPGA) integrated-circuit (IC) chip 200 facing its interconnection substrate 410, an insulating dielectric layer 214 at the active side of its field-programmable-gate-array (FPGA) integrated-circuit (IC) chip 200, wherein each opening in the insulating dielectric layer 214 of its field-programmable-gate-array (FPGA) integrated-circuit (IC) chip 200 may be vertically under a bottom surface of one of the bonding pads 212 of its field-programmable-gate-array (FPGA) integrated-circuit (IC) chip 200, and multiple metal bumps 216 each on the bottom surface of one of the bonding pads 212 of its field-programmable-gate-array (FPGA) integrated-circuit (IC) chip 200 and a bottom surface of the insulating dielectric layer 214 of its field-programmable-gate-array (FPGA) integrated-circuit (IC) chip 200 and having a portion in one of the openings in the insulating dielectric layer 214 of its field-programmable-gate-array (FPGA) integrated-circuit (IC) chip 200 and a bottom end bonded to one of the first bonding pads 412 of its interconnection substrate 410, (4) an underfill 452, such as polymer, between the insulating dielectric layer 214 of its field-programmable-gate-array (FPGA) integrated-circuit (IC) chip 200 and the top of its interconnection substrate 410 and covering a sidewall of each of the metal bumps 216 of its field-programmable-gate-array (FPGA) integrated-circuit (IC) chip 200, (5) a non-volatile memory (NVM) integrated-circuit (IC) chip 300, such as NAND or NOR flash integrated-circuit (IC) chip, magnetoresistive random-access memory (MRAM) integrated-circuit (IC) chip, resistive random-access memory (RRAM) integrated-circuit (IC) chip or ferroelectric random-access memory (FRAM) integrated-circuit (IC) chip, having a backside bonded to a backside of its field-programmable-gate-array (FPGA) integrated-circuit (IC) chip 200 opposite to the active side of its field-programmable-gate-array (FPGA) integrated-circuit (IC) chip 200 via an adhesive or glue layer 419, wherein its non-volatile memory (NVM) integrated-circuit (IC) chip 300 may include multiple bonding pads 302, made of copper or aluminum, at an active side of its non-volatile memory (NVM) integrated-circuit (IC) chip 300 opposite to the backside of its non-volatile memory (NVM) integrated-circuit (IC) chip 300, (6) multiple wirebonded wires 454, made of gold or copper, each having a first end bonded onto one of the bonding pads 302 of its non-volatile memory (NVM) integrated-circuit (IC) chip 300 and a second end bonded onto one of the second bonding pads 414 of its interconnection substrate 410 to couple its non-volatile memory (NVM) integrated-circuit (IC) chip 300 to its interconnection substrate 410, and (7) a molding compound 456 or sealing layer, such as epoxy, on the top of its interconnection substrate 410 and encapsulating its field-programmable-gate-array (FPGA) integrated-circuit (IC) chip 200 and non-volatile memory (NVM) integrated-circuit (IC) chip 300 and each of its wirebonded wires 454, wherein its molding compound 456 may have a sidewall coplanar with, in a vertical direction, a sidewall of its interconnection substrate 410.

Referring to FIG. 3, for the third type of field-programmable multi-chip package 401, in case that its interconnection substrate 410 is a ball-grid-array (BGA) substrate, its ball-grid-array (BGA) substrate 410 may include (1) a core layer, such as FR4, containing epoxy or bismaleimide-triazine (BT) resin and having a thickness between 200 and 1000 micrometers or between 400 and 800 micrometers, wherein FR4 may be a composite material composed of woven fiberglass cloth and an epoxy resin binder, for example, (2) multiple interconnection metal layers, made of copper, each having a thickness between 10 and 50 micrometers, between 25 and 50 micrometers, between 10 and 40 micrometers or between 10 and 20 micrometers and over or under the core layer of its ball-grid-array (BGA) substrate 410, wherein each of the interconnection metal layers of its ball-grid-array (BGA) substrate 410 over the core layer of its ball-grid-array (BGA) substrate 410 may couple to any of the interconnection metal layers of its ball-grid-array (BGA) substrate 410 under the core layer of its ball-grid-array (BGA) substrate 410 through a through hole in the core layer of its ball-grid-array (BGA) substrate 410, (3) multiple polymer layers, i.e., insulating dielectric layers, such as Ajinomoto build-up films (ABFs) or layers of bismaleimide-triazine (BT) resin, each having a thickness between 10 and 50 micrometers, between 15 and 40 micrometers or between 20 and 30 micrometers and over or under the core layer of its ball-grid-array (BGA) substrate 410 and between neighboring two of the interconnection metal layers of its ball-grid-array (BGA) substrate 410, wherein each of the Ajinomoto build-up films (ABFs) may be made of epoxy, phenol hardener, cyanate ester and thermosetting olefin, wherein each of the first, second and third internal interconnects 415, 417 and 418 of its ball-grid-array (BGA) substrate 410 may be provided by each of the interconnection metal layers of its ball-grid-array (BGA) substrate 410, and (4) two solder masks 413, each made of a polymer layer or an insulating dielectric layer having a thickness between 10 and 50 micrometers, between 15 and 40 micrometers or between 20 and 30 micrometers, at the top and bottom of its ball-grid-array (BGA) substrate 410 respectively to cover the topmost and bottommost ones of the interconnection metal layers of its ball-grid-array (BGA) substrate 410 respectively, wherein each of the first and second bonding pads 412 and 414 of its ball-grid-array (BGA) substrate 410 may be provided by the topmost one of the interconnection metal layers of its ball-grid-array (BGA) substrate 410 and at a bottom of an opening in the top one of the two solder masks 413 of its ball-grid-array (BGA) substrate 410, and each of the openings in the top one of the two solder masks 413 of its ball-grid-array (BGA) substrate 410 may be vertically over one of the first and second bonding pads 412 and 414 of its ball-grid-array (BGA) substrate 410, and wherein each of the third bonding pads 416 of its ball-grid-array (BGA) substrate 410 may be provided by the bottommost one of the interconnection metal layers of its ball-grid-array (BGA) substrate 410 and at a top of an opening in the bottom one of the two solder masks 413 of its ball-grid-array (BGA) substrate 410, and each of the openings in the bottom one of the two solder masks 413 of its ball-grid-array (BGA) substrate 410 may be vertically under one of the third bonding pads 416 of its ball-grid-array (BGA) substrate 410.

Referring to FIG. 3, for the third type of field-programmable multi-chip package 401, the insulating dielectric layer 214 of its field-programmable-gate-array (FPGA) integrated-circuit (IC) chip 200 may include an inorganic dielectric layer 222, made of a layer of silicon nitride, silicon oxynitride or silicon oxide having a thickness between 0.1 and 1 micrometers for example, at the active side of its field-programmable-gate-array (FPGA) integrated-circuit (IC) chip 200, wherein each opening 222a in the inorganic dielectric layer 222 thereof may be vertically under one of the bonding pads 212 of its field-programmable-gate-array (FPGA) integrated-circuit (IC) chip 200, and a polymer dielectric layer 224, made of a layer of polyimide, benzocyclobutene (BCB) or parylene having a thickness between 1 and 10 micrometers for example, on a bottom surface of the inorganic dielectric layer 222 thereof, a bottom surface of each of the bonding pads 212 of its field-programmable-gate-array (FPGA) integrated-circuit (IC) chip 200 and a sidewall of each of the openings 222a in the inorganic dielectric layer 222 thereof and in each of the openings 222a in the inorganic dielectric layer 222 thereof, wherein each opening 224a in the polymer dielectric layer 224 thereof may be vertically under one of the bonding pads 212 of its field-programmable-gate-array (FPGA) integrated-circuit (IC) chip 200.

Referring to FIG. 3, for the third type of field-programmable multi-chip package 401, each of the metal bumps 216 of its field-programmable-gate-array (FPGA) integrated-circuit (IC) chip 200 may include (1) an adhesion metal layer 282, such as titanium, titanium nitride, tantalum or tantalum nitride, having a thickness between 1 nm and 50 nm, on the bottom surface of one of the bonding pads 202 of its field-programmable-gate-array (FPGA) integrated-circuit (IC) chip 200, a bottom surface of the polymer dielectric layer 224 of the insulating dielectric layer 214 of its field-programmable-gate-array (FPGA) integrated-circuit (IC) chip 200 and a sidewall of one of the openings 224a in the polymer dielectric layer 224 of the insulating dielectric layer 214 of its field-programmable-gate-array (FPGA) integrated-circuit (IC) chip 200 and in said one of the openings 224a in the polymer dielectric layer 224, (2) an electroplating seed layer 284, such as copper, under and on the adhesion metal layer 282 thereof and in said one of the openings 224a in the polymer dielectric layer 224, (3) an electroplated copper layer 286 having a thickness between 1 μm and 50 μm, 1 μm and 5 μm, 5 μm and 40 μm, 10 μm and 50 μm or 10 μm and 30 μm under and on the electroplating seed layer 284 thereof and in said one of the openings 224a in the polymer dielectric layer 224 and (4) a tin-containing solder cap 288, such as tin or a tin-silver alloy, having a thickness between 10 μm and 100 μm or 20 μm and 50 μm under and on the electroplated copper layer 286 thereof. Each of the metal bumps 216 of its field-programmable-gate-array (FPGA) integrated-circuit (IC) chip 200 may have the tin-containing solder cap 288 bonded to one of the first bonding pads 412 of its interconnection substrate 410.

Referring to FIG. 3, for the third type of field-programmable multi-chip package 401, each of its wirebonded wires 454 may be a low-profiled wirebonded wire having a diameter between 5 and 15 micrometers, wherein the low-profiled wirebonded wire may be compressed at the first end thereof and have a first longitudinal loop 701 extending horizontally from the first end thereof, a second longitudinal loop 702 extending to the second end thereof and a curved loop 703 extending and connecting from the first longitudinal loop 701 thereof to the second longitudinal loop 702 thereof, wherein an angle A between the first and second longitudinal loops 701 and 702 thereof may be between 105 and 120 degrees. A vertical height of each of its wirebonded wires 454 from a top surface of its non-volatile memory (NVM) integrated-circuit (IC) chip 300 at the top thereof may be between 10 and 30 micrometers and its non-volatile memory (NVM) integrated-circuit (IC) chip 300 may have a thickness between 10 and 50 micrometers.

Referring to FIG. 3, for the third type of field-programmable multi-chip package 401, each of a first group of the metal bumps 216 of its field-programmable-gate-array (FPGA) integrated-circuit (IC) chip 200 may couple to its non-volatile memory (NVM) integrated-circuit (IC) chip 300 for signal transmission through, in sequence, one of the second group of the first bonding pads 412 of its interconnection substrate 410, one of the third internal interconnects 418 of its interconnection substrate 410, one of the second group of the second bonding pads 414 of its interconnection substrate 410 and one of its wirebonded wires 454; each of a second group of the metal bumps 216 of its field-programmable-gate-array (FPGA) integrated-circuit (IC) chip 200 may couple to one of its metal bumps 450 for delivery of a voltage of power supply or ground reference or for signal transmission through, in sequence, one of the first group of the first bonding pads 412 of its interconnection substrate 410, one of the first internal interconnects 415 of its interconnection substrate 410 and one of the third bonding pads 416 of its interconnection substrate 410; its non-volatile memory (NVM) integrated-circuit (IC) chip 300 may couple to another of its metal bumps 450 for delivery of a voltage of power supply or ground reference or for signal transmission through, in sequence, another of its wirebonded wires 454, one of the first group of the second bonding pads 414 of its interconnection substrate 410, one of the second internal interconnects 417 of its interconnection substrate 410 and another of the third bonding pads 416 of its interconnection substrate 410.

### Specification for Fourth Type of Field-Programmable Multi-Chip Package

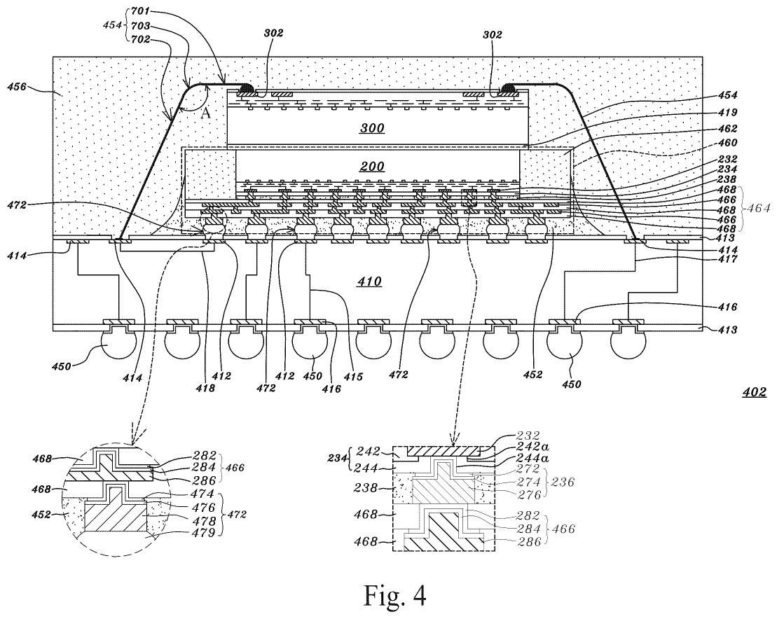

FIG. 4 is a cross-sectional view showing a fourth type of multi-chip package in accordance with an embodiment of the present application. Referring to FIG. 4, a fourth type of field-programmable multi-chip package 402 may be provided with a similar structure to the third type of multi-chip package 401 as illustrated in FIG. 3. For an element indicated by the same reference number shown in FIGS. 3 and 4, the specification of the element as seen in FIG. 4 may be referred to that of the element as illustrated in FIG. 3. The difference therebetween is mentioned as below: the field-programmable-gate-array (FPGA) integrated-circuit (IC) chip 200 of the third type of multi-chip package 401 may be replaced with a field-programmable chip package 460 for the fourth type of field-programmable multi-chip package 402. For the fourth type of field-programmable multi-chip package 402, its field-programmable chip package 460 may include (1) a field-programmable-gate-array (FPGA) integrated-circuit (IC) chip 200 having multiple bonding pads 232, made of a copper or aluminum layer having a thickness between 0.1 and 2 micrometers for example, at an active side of the field-programmable-gate-array (FPGA) integrated-circuit (IC) chip 200 thereof facing its interconnection substrate 410, an insulating dielectric layer 234 at the active side of the field-programmable-gate-array (FPGA) integrated-circuit (IC) chip 200 thereof, wherein each opening in the insulating dielectric layer 234 of the field-programmable-gate-array (FPGA) integrated-circuit (IC) chip 200 thereof may be vertically under a bottom surface of one of the bonding pads 212 of the field-programmable-gate-array (FPGA) integrated-circuit (IC) chip 200 thereof, multiple metal bumps or pads 236 each on the bottom surface of one of the bonding pads 232 of the field-programmable-gate-array (FPGA) integrated-circuit (IC) chip 200 thereof and a bottom surface of the insulating dielectric layer 234 of the field-programmable-gate-array (FPGA) integrated-circuit (IC) chip 200 thereof and having a portion in one of the openings in the insulating dielectric layer 234 of the field-programmable-gate-array (FPGA) integrated-circuit (IC) chip 200 thereof, and an insulating dielectric layer 238, such as polymer layer, on a bottom surface of the insulating dielectric layer 234 of the field-programmable-gate-array (FPGA) integrated-circuit (IC) chip 200 thereof and covering a sidewall of each of the metal bumps or pads 236 thereof, wherein the insulating dielectric layer 238 of the field-programmable-gate-array (FPGA) integrated-circuit (IC) chip 200 thereof may have a bottom surface substantially coplanar with a bottom surface of each of the metal bumps or pads 236 of the field-programmable-gate-array (FPGA) integrated-circuit (IC) chip 200 thereof, (2) a molding compound 462 or sealing layer, containing a polymer, such as epoxy or polyimide, and greater than 80 percentages by weight of silicon oxide, horizontally around the field-programmable-gate-array (FPGA) integrated-circuit (IC) chip 200 thereof and having a top surface substantially coplanar with a backside of the field-programmable-gate-array (FPGA) integrated-circuit (IC) chip 200 thereof and a bottom surface substantially coplanar with the bottom surface of the insulating dielectric layer 238 of the field-programmable-gate-array (FPGA) integrated-circuit (IC) chip 200 thereof and the bottom surface of each of the metal bumps or pads 236 of the field-programmable-gate-array (FPGA) integrated-circuit (IC) chip 200 thereof, (3) an interconnection scheme 464 under and on the insulating dielectric layer 238 of the field-programmable-gate-array (FPGA) integrated-circuit (IC) chip 200 thereof and the molding compound 462 thereof, wherein the interconnection scheme 464 thereof may include one or more interconnection metal layers 466 under the field-programmable-gate-array (FPGA) integrated-circuit (IC) chip 200 thereof and the molding compound 462 thereof and across an edge of the field-programmable-gate-array (FPGA) integrated-circuit (IC) chip 200 thereof, and one or more insulating dielectric layers 468 each between neighboring two of the one or more interconnection metal layers 466 of the interconnection scheme 464 thereof, under and on the bottommost one of the one or more interconnection metal layers 466 of the interconnection scheme 464 thereof or over and on the topmost one of the one or more interconnection metal layers 466 of the interconnection scheme 464 thereof, wherein a lower one of the one or more interconnection metal layers 466 of the interconnection scheme 464 of its field-programmable chip package 460 may extend into each of the openings in one of the one or more insulating dielectric layers 468 of the interconnection scheme 464 of its field-programmable chip package 460 to contact a bottom surface of an upper one of the one or more interconnection metal layers 466 of the interconnection scheme 464 of its field-programmable chip package 460 and wherein each opening in the bottommost one of the one or more insulating dielectric layers 468 of the interconnection scheme 464 thereof may be vertically under a bottom surface of a bonding pad of the bottommost one of the one or more interconnection metal layers 466 of the interconnection scheme 464 thereof, and (4) multiple metal bumps 472 each on the bottom surface of one of the bonding pads 232 of the bottommost one of the one or more interconnection metal layers 466 of the interconnection scheme 464 thereof and a bottom surface of the bottommost one of the one or more insulating dielectric layers 468 of the interconnection scheme 464 thereof and having a portion in one of the openings in the bottommost one of the one or more insulating dielectric layers 468 of the interconnection scheme 464 thereof and a bottom end bonded to one of the first bonding pads 412 of its interconnection substrate 410.

Referring to FIG. 4, for the fourth type of field-programmable multi-chip package 402, the insulating dielectric layer 234 of the field-programmable-gate-array (FPGA) integrated-circuit (IC) chip 200 of its field-programmable chip package 460 may include an inorganic dielectric layer 242, made of a layer of silicon nitride, silicon oxynitride or silicon oxide having a thickness between 0.1 and 1 micrometers for example, at the active side of the field-programmable-gate-array (FPGA) integrated-circuit (IC) chip 200 of its field-programmable chip package 460, wherein each opening 242a in the inorganic dielectric layer 242 thereof may be vertically under one of the bonding pads 232 of the field-programmable-gate-array (FPGA) integrated-circuit (IC) chip 200 of its field-programmable chip package 460, and a polymer dielectric layer 244, made of a layer of polyimide, benzocyclobutene (BCB) or parylene having a thickness between 1 and 10 micrometers for example, on a bottom surface of the inorganic dielectric layer 242 thereof, a bottom surface of each of the bonding pads 232 of the field-programmable-gate-array (FPGA) integrated-circuit (IC) chip 200 of its field-programmable chip package 460 and a sidewall of each of the openings 242a in the inorganic dielectric layer 242 thereof and in each of the openings 242a in the inorganic dielectric layer 242 thereof, wherein each opening 244a in the polymer dielectric layer 244 thereof may be vertically under one of the bonding pads 232 of the field-programmable-gate-array (FPGA) integrated-circuit (IC) chip 200 of its field-programmable chip package 460.

Referring to FIG. 4, for the fourth type of field-programmable multi-chip package 402, each of the metal bumps or pads 236 of the field-programmable-gate-array (FPGA) integrated-circuit (IC) chip 200 of its field-programmable chip package 460 may include (1) an adhesion metal layer 272, such as titanium, titanium nitride, tantalum or tantalum nitride, having a thickness between 1 nm and 50 nm, on the bottom surface of one of the bonding pads 232 of the field-programmable-gate-array (FPGA) integrated-circuit (IC) chip 200 of its field-programmable chip package 460, a bottom surface of the polymer dielectric layer 244 of the insulating dielectric layer 234 of the field-programmable-gate-array (FPGA) integrated-circuit (IC) chip 200 of its field-programmable chip package 460 and a sidewall of one of the openings 244a in the polymer dielectric layer 244 of the insulating dielectric layer 234 of the field-programmable-gate-array (FPGA) integrated-circuit (IC) chip 200 of its field-programmable chip package 460 and in said one of the openings 244a in the polymer dielectric layer 244, (2) an electroplating seed layer 274, such as copper, under and on the adhesion metal layer 272 thereof and in said one of the openings 244a in the polymer dielectric layer 244, and (3) an electroplated copper layer 276 having a thickness between 1 μm and 50 μm, 1 μm and 5 μm, 5 μm and 40 μm, 10 μm and 50 μm or 10 μm and 30 μm under and on the electroplating seed layer 274 thereof, in said one of the openings 244a in the polymer dielectric layer 244 and having a sidewall covered by the insulating dielectric layer 238 of the field-programmable-gate-array (FPGA) integrated-circuit (IC) chip 200 of its field-programmable chip package 460 and a bottom surface substantially coplanar with the bottom surface of the insulating dielectric layer 238 of the field-programmable-gate-array (FPGA) integrated-circuit (IC) chip 200 of its field-programmable chip package 460 and the bottom surface of the molding compound 462 of its field-programmable chip package 460.

Referring to FIG. 4, for the fourth type of field-programmable multi-chip package 402, the topmost one of the one or more insulating dielectric layers 468 of the interconnection scheme 464 of its field-programmable chip package 460 may horizontally extend between the insulating dielectric layer 238 of the field-programmable-gate-array (FPGA) integrated-circuit (IC) chip 200 of its field-programmable chip package 460 and the topmost one of the one or more interconnection metal layers 466 of the interconnection scheme 464 of its field-programmable chip package 460 and between the molding compound 462 of its field-programmable chip package 460 and the topmost one of the one or more interconnection metal layers 466 of the interconnection scheme 464 of its field-programmable chip package 460. Each opening in the topmost one of the one or more insulating dielectric layers 468 of the interconnection scheme 464 of its field-programmable chip package 460 may be vertically under the bottom surface of the electroplated copper layer 276 of one of the metal bumps or pads 236 of the field-programmable-gate-array (FPGA) integrated-circuit (IC) chip 200 of its field-programmable chip package 460. The topmost one of the one or more interconnection metal layers 466 of the interconnection scheme 464 of its field-programmable chip package 460 may extend into each of the openings in the topmost one of the one or more insulating dielectric layers 468 of the interconnection scheme 464 of its field-programmable chip package 460 to contact the bottom surface of the electroplated copper layer 276 of one of the metal bumps or pads 236 of the field-programmable-gate-array (FPGA) integrated-circuit (IC) chip 200 of its field-programmable chip package 460. Each of the one or more interconnection metal layers 466 of the interconnection scheme 464 of its field-programmable chip package 460 may include (1) a bulk metal layer 486, such as copper layer having a thickness between 0.3 μm and 20 μm, (2) an adhesion metal layer 482, such as a layer of titanium, titanium nitride, tantalum or tantalum nitride having a thickness between 1 nm and 50 nm, at a top of the bulk metal layer 486 thereof but not at a sidewall of the bulk metal layer 486 thereof, and on a bottom surface of an upper one of the one or more insulating dielectric layers 468 of the interconnection scheme 464 of its field-programmable chip package 460, and (3) an electroplating seed layer 484, such as copper, between the bulk metal layer 486 thereof and the adhesion metal layer 482 thereof, wherein a lower one of the one or more insulating dielectric layers 468 of the interconnection scheme 464 of its field-programmable chip package 460 may be on a bottom surface of the bulk metal layer 486 thereof and cover the sidewall of the bulk metal layer 486 thereof. Each of the one or more interconnection metal layers 466 of the interconnection scheme 464 of its field-programmable chip package 460 may be patterned with a metal line or trace having a thickness between, for example, 0.3 μm and 20 μm, 0.5 μm and 10 μm, 1 μm and 5 μm, 1 μm and 10 μm, or 2 μm and 10 μm, or thicker than or equal to 0.3 μm, 0.5 μm, 0.7 μm, 1 μm, 1.5 μm, 2 μm or 3 μm and a width between, for example, 0.3 μm and 20 μm, 0.5 μm and 10 μm, 1 μm and 5 μm, 1 μm and 10 μm, or 2 μm and 10 μm, or wider than or equal to 0.3 μm, 0.5 μm, 0.7 μm, 1 μm, 1.5 μm, 2 μm or 3 μm. Each of the one or more insulating dielectric layers 468 of the interconnection scheme 464 of its field-programmable chip package 460 may be made of a polymer layer, such as polyimide, benzocyclobutene (BCB), parylene, epoxy-based material or compound, photo epoxy SU-8, elastomer or silicone, having a thickness between 0.3 μm and 20 μm, 0.5 μm and 10 μm, 1 μm and 5 μm, or 1 μm and 10 μm or thicker than or equal to 0.3 μm, 0.5 μm, 0.7 μm, 1 μm, 1.5 μm, 2 μm or 3 μm.

Referring to FIG. 4, for the fourth type of field-programmable multi-chip package 402, each of the metal bumps 472 of its field-programmable chip package 460 may include (1) an adhesion metal layer 474, such as titanium, titanium nitride, tantalum or tantalum nitride, having a thickness between 1 nm and 50 nm, on the bottom surface of one of the bonding pads 232 of the bottommost one of the one or more interconnection metal layers 466 of the interconnection scheme 464 of its field-programmable chip package 460, the bottom surface of the bottommost one of the one or more insulating dielectric layers 468 of the interconnection scheme 464 of its field-programmable chip package 460 and a sidewall of one of the openings in the bottommost one of the one or more insulating dielectric layers 468 of the interconnection scheme 464 of its field-programmable chip package 460 and in said one of the openings in the bottommost one of the one or more insulating dielectric layers 468, (2) an electroplating seed layer 476, such as copper, under and on the adhesion metal layer 474 thereof and in said one of the openings in the bottommost one of the one or more insulating dielectric layers 468, (3) an electroplated copper layer 478 having a thickness between 1 μm and 50 μm, 1 μm and 5 μm, 5 μm and 40 μm, 10 μm and 50 μm or 10 μm and 30 μm under and on the electroplating seed layer 476 thereof and in said one of the openings in the bottommost one of the one or more insulating dielectric layers 468 and (4) a tin-containing solder cap 479, such as tin or a tin-silver alloy, having a thickness between 10 μm and 100 μm or 20 μm and 50 μm under and on the electroplated copper layer 478 thereof. Each of the metal bumps 472 of its field-programmable chip package 460 may have the tin-containing solder cap 479 bonded to one of the first bonding pads 412 of its interconnection substrate 410.

Referring to FIG. 4, for the fourth type of field-programmable multi-chip package 402, its underfill 452, such as polymer, may be formed between the bottommost one of the one or more insulating dielectric layers 468 of the interconnection scheme 464 of its field-programmable chip package 460 and the top of its interconnection substrate 410 and covering a sidewall of each of the metal bumps 472 of its field-programmable chip package 460. Its non-volatile memory (NVM) integrated-circuit (IC) chip 300 may have the backside bonded to a backside of a silicon substrate of the field-programmable-gate-array (FPGA) integrated-circuit (IC) chip 200 of its field-programmable chip package 460 via its adhesive or glue layer 419 and bonded to a backside of the molding compound 462 of its field-programmable chip package 460 via its adhesive or glue layer 419. Its molding compound 456 or sealing layer, such as epoxy, may be formed on the top of its interconnection substrate 410 and encapsulating its field-programmable chip package 460 and non-volatile memory (NVM) integrated-circuit (IC) chip 300 and each of its wirebonded wires 454, wherein its molding compound 456 may have a sidewall coplanar with, in a vertical direction, a sidewall of its interconnection substrate 410.

Referring to FIG. 4, for the fourth type of field-programmable multi-chip package 402, each of a first group of the metal bumps or pads 236 of the field-programmable-gate-array (FPGA) integrated-circuit (IC) chip 200 of its field-programmable chip package 460 may couple to its non-volatile memory (NVM) integrated-circuit (IC) chip 300 for signal transmission through, in sequence, each of the one or more interconnection metal layers 466 of the interconnection scheme 464 of its field-programmable chip package 460, one of a first group of the metal bumps 472 of its field-programmable chip package 460, one of the second group of the first bonding pads 412 of its interconnection substrate 410, one of the third internal interconnects 418 of its interconnection substrate 410, one of the second group of the second bonding pads 414 of its interconnection substrate 410 and one of its wirebonded wires 454; each of a second group of the metal bumps or pads 236 of the field-programmable-gate-array (FPGA) integrated-circuit (IC) chip 200 of its field-programmable chip package 460 may couple to one of its metal bumps 450 for delivery of a voltage of power supply or ground reference or for signal transmission through, in sequence, each of the one or more interconnection metal layers 466 of the interconnection scheme 464 of its field-programmable chip package 460, one of a second group of the metal bumps 472 of its field-programmable chip package 460, one of the first group of the first bonding pads 412 of its interconnection substrate 410, one of the first internal interconnects 415 of its interconnection substrate 410 and one of the third bonding pads 416 of its interconnection substrate 410; its non-volatile memory (NVM) integrated-circuit (IC) chip 300 may couple to another of its metal bumps 450 for delivery of a voltage of power supply or ground reference or for signal transmission through, in sequence, another of its wirebonded wires 454, one of the first group of the second bonding pads 414 of its interconnection substrate 410, one of the second internal interconnects 417 of its interconnection substrate 410 and another of the third bonding pads 416 of its interconnection substrate 410.

### Specification for Fifth Type of Field-Programmable Multi-Chip Package

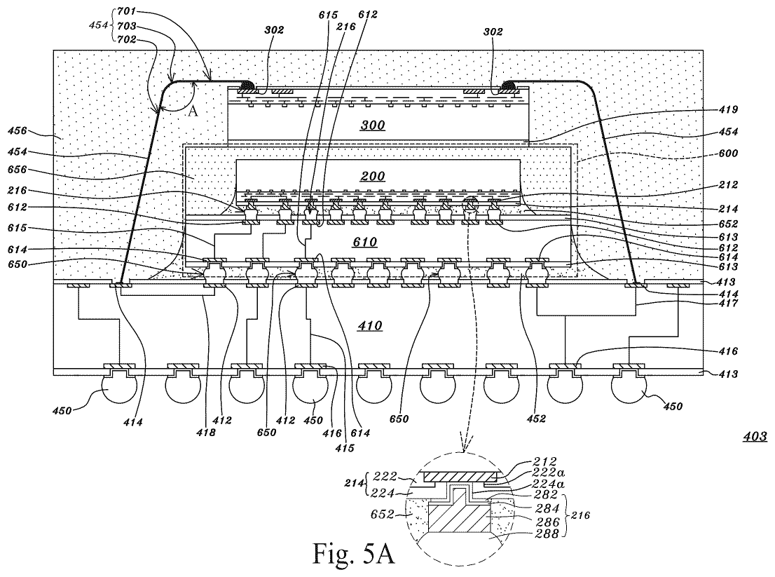

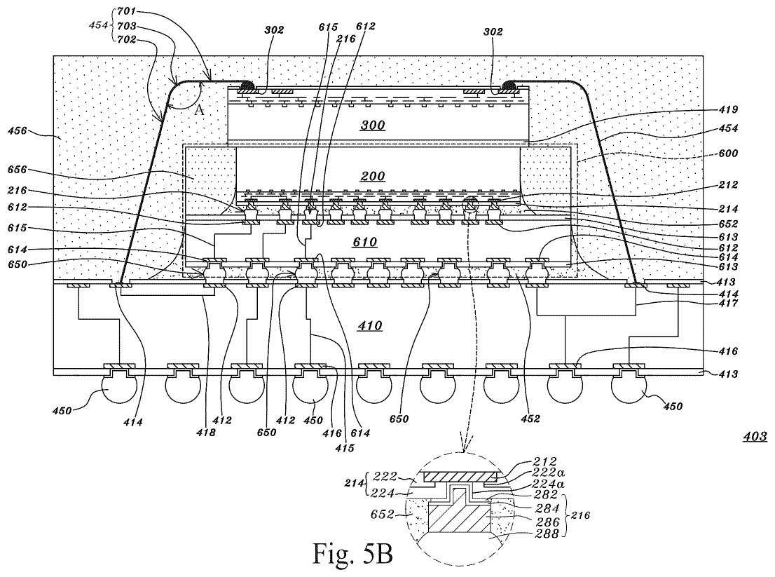

FIGS. 5A and 5B are cross-sectional views showing a fifth type of multi-chip package in accordance with an embodiment of the present application. Referring to FIGS. 5A and 5B, a fifth type of field-programmable multi-chip package 403 may be provided with a similar structure to the third type of multi-chip package 401 as illustrated in FIG. 3. For an element indicated by the same reference number shown in FIGS. 3, 5A and 5B, the specification of the element as seen in FIGS. 5A and 5B may be referred to that of the element as illustrated in FIG. 3. The difference therebetween is mentioned as below: the field-programmable-gate-array (FPGA) integrated-circuit (IC) chip 200 of the third type of multi-chip package 401 may be replaced with a field-programmable chip package 600 for the fifth type of field-programmable multi-chip package 403. For the fifth type of field-programmable multi-chip package 403, its field-programmable chip package 600 may include (1) an interconnection substrate 610, e.g., ball-grid-array (BGA) substrate, including multiple first bonding pads 612 at a top of the interconnection substrate 610 thereof and multiple second bonding pads 614 at a bottom of the interconnection substrate 610 thereof opposite to the top of the interconnection substrate 610 thereof, wherein each of the first bonding pads 612 of the interconnection substrate 610 thereof may couple to one or more of the second bonding pads 614 of the interconnection substrate 610 thereof via an internal interconnect 615 of the interconnection substrate 610 thereof, (2) multiple metal bumps 650, such as solder bumps, in an array each having a top end bonded to one of the second bonding pads 614 of the interconnection substrate 610 thereof to act as the external pin of its field-programmable chip package 600 for coupling to an external circuit outside of its field-programmable chip package 600, wherein each of the metal bumps 650 thereof may have a bottom end bonded to one of the first bonding pads 412 of its interconnection substrate 410 and may be made of a lead-free solder containing tin, copper, silver, bismuth, indium, zinc, antimony and/or traces of other metals, e.g., Sn—Ag—Cu (SAC) solder, Sn—Ag solder or Sn—Ag—Cu—Zn solder, (3) a field-programmable-gate-array (FPGA) integrated-circuit (IC) chip 200 having the same specification as that illustrated in FIG. 3, wherein the field-programmable-gate-array (FPGA) integrated-circuit (IC) chip 200 thereof may have the bonding pads 212 at the active side of the field-programmable-gate-array (FPGA) integrated-circuit (IC) chip 200 thereof facing the interconnection substrate 610 thereof, the insulating dielectric layer 214 at the active side of the field-programmable-gate-array (FPGA) integrated-circuit (IC) chip 200 thereof, and the metal bumps 216 each having a bottom end, i.e., the tin-containing solder cap 288 thereof, bonded to one of the first bonding pads 612 of the interconnection substrate 610 thereof, (4) an underfill 652, such as polymer, between the insulating dielectric layer 214 of the field-programmable-gate-array (FPGA) integrated-circuit (IC) chip 200 thereof and the top of the interconnection substrate 610 thereof and covering a sidewall of each of the metal bumps 216 of the field-programmable-gate-array (FPGA) integrated-circuit (IC) chip 200 thereof, and (5) a molding compound 656 or sealing layer, such as epoxy, on the top of the interconnection substrate 610 thereof and encapsulating the field-programmable-gate-array (FPGA) integrated-circuit (IC) chip 200 thereof, wherein the molding compound 456 thereof may have a sidewall coplanar with, in a vertical direction, a sidewall of the interconnection substrate 610 thereof.

Referring to FIGS. 5A and 5B, for the fifth type of field-programmable multi-chip package 403, in case that the interconnection substrate 610 of its field-programmable chip package 600 is a ball-grid-array (BGA) substrate, the ball-grid-array (BGA) substrate 610 may include (1) a core layer, such as FR4, containing epoxy or bismaleimide-triazine (BT) resin and having a thickness between 200 and 1000 micrometers or between 400 and 800 micrometers, wherein FR4 may be a composite material composed of woven fiberglass cloth and an epoxy resin binder, for example, (2) multiple interconnection metal layers, made of copper, each having a thickness between 10 and 50 micrometers, between 25 and 50 micrometers, between 10 and 40 micrometers or between 10 and 20 micrometers and over or under the core layer of the ball-grid-array (BGA) substrate 610, wherein each of the interconnection metal layers of the ball-grid-array (BGA) substrate 610 over the core layer of the ball-grid-array (BGA) substrate 610 may couple to any of the interconnection metal layers of the ball-grid-array (BGA) substrate 610 under the core layer of the ball-grid-array (BGA) substrate 610 through a through hole in the core layer of the ball-grid-array (BGA) substrate 610, (3) multiple polymer layers, i.e., insulating dielectric layers, such as Ajinomoto build-up films (ABFs) or layers of bismaleimide-triazine (BT) resin, each having a thickness between 10 and 50 micrometers, between 15 and 40 micrometers or between 20 and 30 micrometers and over or under the core layer of the ball-grid-array (BGA) substrate 610 and between neighboring two of the interconnection metal layers of the ball-grid-array (BGA) substrate 610, wherein each of the Ajinomoto build-up films (ABFs) may be made of epoxy, phenol hardener, cyanate ester and thermosetting olefin, wherein each of the internal interconnect 615 of the ball-grid-array (BGA) substrate 610 may be provided by each of the interconnection metal layers of the ball-grid-array (BGA) substrate 610, and (4) two solder masks 613, each made of a polymer layer or an insulating dielectric layer having a thickness between 10 and 50 micrometers, between 15 and 40 micrometers or between 20 and 30 micrometers, at the top and bottom of the ball-grid-array (BGA) substrate 610 respectively to cover the topmost and bottommost ones of the interconnection metal layers of the ball-grid-array (BGA) substrate 610 respectively, wherein each of the first bonding pads 612 of the ball-grid-array (BGA) substrate 610 may be provided by the topmost one of the interconnection metal layers of the ball-grid-array (BGA) substrate 610 and at a bottom of an opening in the top one of the two solder masks 613 of the ball-grid-array (BGA) substrate 610, and each of the openings in the top one of the two solder masks 613 of the ball-grid-array (BGA) substrate 610 may be vertically over one of the first bonding pads 612 of the ball-grid-array (BGA) substrate 610, and wherein each of the second bonding pads 614 of the ball-grid-array (BGA) substrate 610 may be provided by the bottommost one of the interconnection metal layers of the ball-grid-array (BGA) substrate 610 and at a top of an opening in the bottom one of the two solder masks 613 of the ball-grid-array (BGA) substrate 610, and each of the openings in the bottom one of the two solder masks 613 of the ball-grid-array (BGA) substrate 610 may be vertically under one of the second bonding pads 614 of the ball-grid-array (BGA) substrate 610.

Referring to FIGS. 5A and 5B, for the fifth type of field-programmable multi-chip package 404, its underfill 452, such as polymer, may be formed between the bottom of the interconnection substrate 610 of its field-programmable chip package 600 and the top of its interconnection substrate 410 and covering a sidewall of each of the metal bumps 650 of its field-programmable chip package 600. Its molding compound 456 or sealing layer, such as epoxy, may be formed on the top of its interconnection substrate 410 and encapsulating its field-programmable chip package 600 and non-volatile memory (NVM) integrated-circuit (IC) chip 300 and each of its wirebonded wires 454, wherein its molding compound 456 may have a sidewall coplanar with, in a vertical direction, a sidewall of its interconnection substrate 410.

For a first alternative as seen in FIG. 5A, for the fifth type of field-programmable multi-chip package 404, its non-volatile memory (NVM) integrated-circuit (IC) chip 300 may have the backside bonded to a top of its field-programmable chip package 600, i.e., a top of the molding compound 656 thereof, via its adhesive or glue layer 419, wherein a top portion of the molding compound 656 of its field-programmable chip package 600 may be kept between its non-volatile memory (NVM) integrated-circuit (IC) chip 300 and the field-programmable-gate-array (FPGA) integrated-circuit (IC) chip 200 of its field-programmable chip package 600, i.e., a backside of a silicon substrate thereof.

For a second alternative as seen in FIG. 5B, for the fifth type of field-programmable multi-chip package 404, its non-volatile memory (NVM) integrated-circuit (IC) chip 300 may have the backside bonded to a top of its field-programmable chip package 600, i.e., a backside of a silicon substrate of the field-programmable-gate-array (FPGA) integrated-circuit (IC) chip 200 thereof and a top of the molding compound 656 thereof, via its adhesive or glue layer 419, wherein the backside of the silicon substrate of the field-programmable-gate-array (FPGA) integrated-circuit (IC) chip 200 of its field-programmable chip package 600 is coplanar with the top of the molding compound 656 of its field-programmable chip package 600 and the molding compound 656 of its field-programmable chip package 600 has no portion kept between its non-volatile memory (NVM) integrated-circuit (IC) chip 300 and the field-programmable-gate-array (FPGA) integrated-circuit (IC) chip 200 of its field-programmable chip package 600.

Referring to FIGS. 5A and 5B, for the fifth type of field-programmable multi-chip package 403, each of a first group of the metal bumps 216 of the field-programmable-gate-array (FPGA) integrated-circuit (IC) chip 200 of its field-programmable chip package 600 may couple to its non-volatile memory (NVM) integrated-circuit (IC) chip 300 for signal transmission through, in sequence, one of the first bonding pads 612 of the interconnection substrate 610 of its field-programmable chip package 600, one of the internal interconnects 615 of the interconnection substrate 610 of its field-programmable chip package 600, one of the second bonding pads 614 of the interconnection substrate 610 of its field-programmable chip package 600, one of the metal bumps 650 of its field-programmable chip package 600, one of the second group of the first bonding pads 412 of its interconnection substrate 410, one of the third internal interconnects 418 of its interconnection substrate 410, one of the second group of the second bonding pads 414 of its interconnection substrate 410 and one of its wirebonded wires 454; each of a second group of the metal bumps 216 of the field-programmable-gate-array (FPGA) integrated-circuit (IC) chip 200 of its field-programmable chip package 600 may couple to one of its metal bumps 450 for delivery of a voltage of power supply or ground reference or for signal transmission through, in sequence, another of the first bonding pads 612 of the interconnection substrate 610 of its field-programmable chip package 600, another of the internal interconnects 615 of the interconnection substrate 610 of its field-programmable chip package 600, another of the second bonding pads 614 of the interconnection substrate 610 of its field-programmable chip package 600, another of the metal bumps 650 of its field-programmable chip package 600, one of the first group of the first bonding pads 412 of its interconnection substrate 410, one of the first internal interconnects 415 of its interconnection substrate 410 and one of the third bonding pads 416 of its interconnection substrate 410; its non-volatile memory (NVM) integrated-circuit (IC) chip 300 may couple to another of its metal bumps 450 for delivery of a voltage of power supply or ground reference or for signal transmission through, in sequence, another of its wirebonded wires 454, one of the first group of the second bonding pads 414 of its interconnection substrate 410, one of the second internal interconnects 417 of its interconnection substrate 410 and another of the third bonding pads 416 of its interconnection substrate 410.

### Specification for Sixth Type of Field-Programmable Multi-Chip Package

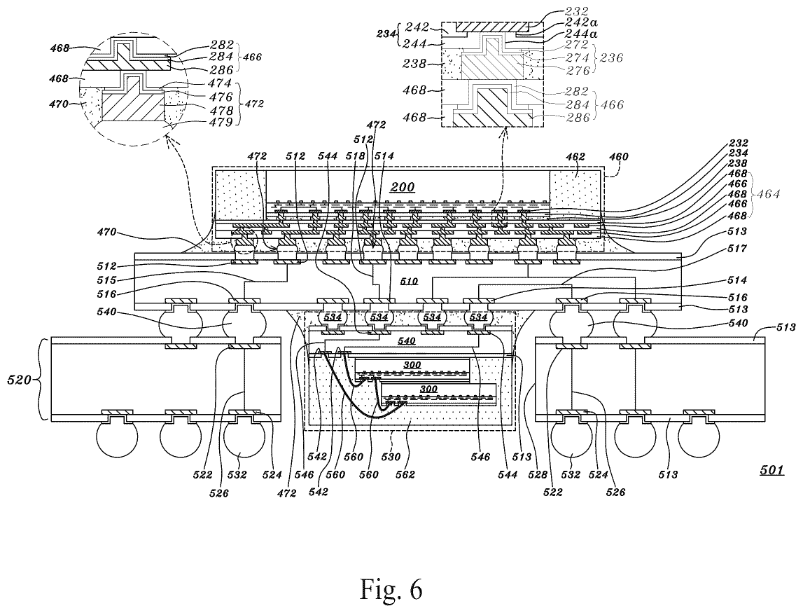

FIG. 6 is a cross-sectional view showing a sixth type of multi-chip package in accordance with an embodiment of the present application. Referring to FIG. 6, a sixth type of field-programmable multi-chip package 501 may comprise (1) an interconnection substrate 510, e.g., ball-grid-array (BGA) substrate, including multiple first bonding pads 512 at a top of its interconnection substrate 510, multiple second bonding pads 514 at a bottom of its interconnection substrate 510 opposite to the top of its interconnection substrate 510 and multiple third bonding pads 516 at the bottom of its interconnection substrate 510 and horizontally surrounding the second bonding pads 514 of its interconnection substrate 510, wherein each of a first group of the first bonding pads 512 of its interconnection substrate 510 may couple to one or more of the third bonding pads 516 of its interconnection substrate 510 via a first internal interconnect 515 of its interconnection substrate 510, each of a first group of the second bonding pads 514 of its interconnection substrate 510 may couple to one or more of the third bonding pads 516 of its interconnection substrate 510 via a second internal interconnect 517 of its interconnection substrate 510, and each of a second group of the first bonding pads 512 of its interconnection substrate 510 may couple to one or more of a second group of the second bonding pads 514 of its interconnection substrate 510 via a third internal interconnect 518 of its interconnection substrate 510, (2) a field-programmable chip package 460, having the same specification as one illustrated in FIG. 4, having the metal bumps 472 each having a bottom end, i.e., the tin-containing solder cap 479 thereof, bonded to one of the first bonding pads 512 of its interconnection substrate 510, (3) a non-volatile memory (NVM) chip package 530 bonded to the bottom of its interconnection substrate 510, (4) an interconnection substrate 520, e.g., ball-grid-array (BGA) substrate, including multiple first bonding pads 522 at a top of its interconnection substrate 520 and multiple second bonding pads 524 at a bottom of its interconnection substrate 520 opposite to the top of its interconnection substrate 520, wherein each of the first bonding pads 522 of its interconnection substrate 520 may couple to one or more of the second bonding pads 524 of its interconnection substrate 520 via an internal interconnect 526 of its interconnection substrate 520, wherein a through hole 528 in its interconnection substrate 520 may accommodate its non-volatile memory (NVM) chip package 530, (5) multiple metal bumps 540, such as solder bumps, in an array each between its interconnection substrates 510 and 520 and having a top end bonded onto one of the third bonding pads 516 of its interconnection substrate 510 and a bottom end bonded onto one of the first bonding pads 522 of its interconnection substrate 520, wherein each of its metal bumps 540 may be made of a lead-free solder containing tin, copper, silver, bismuth, indium, zinc, antimony and/or traces of other metals, e.g., Sn—Ag—Cu (SAC) solder, Sn—Ag solder or Sn—Ag—Cu—Zn solder, (6) multiple metal bumps 532, such as solder bumps, in an array each having a top end bonded onto one of the second bonding pads 524 of its interconnection substrate 520 to act as its external pin for coupling to an external circuit outside of the sixth type of field-programmable multi-chip package 501, wherein each of its metal bumps 532 may be made of a lead-free solder containing tin, copper, silver, bismuth, indium, zinc, antimony and/or traces of other metals, e.g., Sn—Ag—Cu (SAC) solder, Sn—Ag solder or Sn—Ag—Cu—Zn solder, and (7) an underfill 470, such as polymer, between the bottommost one of the one or more insulating dielectric layers 468 of the interconnection scheme 464 of its field-programmable chip package 460 and the top of its interconnection substrate 510 and covering a sidewall of each of the metal bumps 472 of its field-programmable chip package 460.

Referring to FIG. 6, for the sixth type of field-programmable multi-chip package 501, its non-volatile memory (NVM) chip package 530 may include (1) an interconnection substrate 540, e.g., ball-grid-array (BGA) substrate, including multiple first bonding pads 542 at a bottom of the interconnection substrate 540 thereof and multiple second bonding pads 544 at top bottom of the interconnection substrate 540 thereof opposite to the bottom of the interconnection substrate 540 thereof, wherein each of the first bonding pads 542 of the interconnection substrate 540 thereof may couple to one or more of the second bonding pads 544 of the interconnection substrate 540 thereof via an internal interconnect 546 of the interconnection substrate 540 thereof, (2) multiple metal bumps 534, such as solder bumps, in an array each having a bottom end bonded to one of the second bonding pads 544 of the interconnection substrate 540 thereof and a top end bonded to one of the second bonding pads 514 of its interconnection substrate 510, wherein each of the metal bumps 534 thereof may be made of a lead-free solder containing tin, copper, silver, bismuth, indium, zinc, antimony and/or traces of other metals, e.g., Sn—Ag—Cu (SAC) solder, Sn—Ag solder or Sn—Ag—Cu—Zn solder, (3) multiple non-volatile memory (NVM) integrated-circuit (IC) chips 300, each of which may be a NAND or NOR flash integrated-circuit (IC) chip, magnetoresistive random-access memory (MRAM) integrated-circuit (IC) chip, resistive random-access memory (RRAM) integrated-circuit (IC) chip or ferroelectric random-access memory (FRAM) integrated-circuit (IC) chip, under the interconnection substrate 540 thereof, wherein each of the non-volatile memory (NVM) integrated-circuit (IC) chips 300 thereof may have an active side at a bottom side of said each of the non-volatile memory (NVM) integrated-circuit (IC) chips 300 thereof and a backside opposite to the active side of said each of the non-volatile memory (NVM) integrated-circuit (IC) chips 300 thereof and at a top side of said each of the non-volatile memory (NVM) integrated-circuit (IC) chips 300 thereof, wherein each of the non-volatile memory (NVM) integrated-circuit (IC) chip 300 thereof may include multiple bonding pads 302, made of a copper or aluminum layer having a thickness between 0.1 and 2 micrometers for example, at the active side of said each of the non-volatile memory (NVM) integrated-circuit (IC) chips 300 and wherein a lower one of the non-volatile memory (NVM) integrated-circuit (IC) chips 300 thereof may have the backside bonded to the active side of an upper one of the non-volatile memory (NVM) integrated-circuit (IC) chips 300 thereof via an adhesive or glue layer 552 and the topmost one of the non-volatile memory (NVM) integrated-circuit (IC) chips 300 thereof may have the backside bonded to the bottom of the interconnection substrate 540 thereof via an adhesive or glue layer 554, (4) multiple wirebonded wires 560, made of gold or copper, each having an end bonded onto one of the bonding pads 302 of one of the non-volatile memory (NVM) integrated-circuit (IC) chips 300 thereof and the other end bonded onto one of the bonding pads 302 of another of the non-volatile memory (NVM) integrated-circuit (IC) chips 300 thereof or onto one of the first bonding pads 542 of the interconnection substrate 540 thereof, and (5) a molding compound 562 or sealing layer, such as epoxy, on the bottom of the interconnection substrate 540 thereof and encapsulating each of the non-volatile memory (NVM) integrated-circuit (IC) chips 300 thereof and each of the wirebonded wires 560, wherein the molding compound 562 thereof may have a sidewall coplanar with, in a vertical direction, a sidewall of the interconnection substrate 540 thereof. The sixth type of field-programmable multi-chip package 501 may further include an underfill 472, such as polymer, between the top of the interconnection substrate 540 of its non-volatile memory (NVM) chip package 530 and the bottom of its interconnection substrate 510 and covering a sidewall of each of the metal bumps 534 of its non-volatile memory (NVM) chip package 530.

Referring to FIG. 6, for the sixth type of field-programmable multi-chip package 501, in case that each of its interconnection substrates 510 and 520 and the interconnection substrate 540 of its non-volatile memory (NVM) chip package 530 is a ball-grid-array (BGA) substrate, its ball-grid-array (BGA) substrate 510, 520 or 530 may include (1) a core layer, such as FR4, containing epoxy or bismaleimide-triazine (BT) resin and having a thickness between 200 and 1000 micrometers or between 400 and 800 micrometers, wherein FR4 may be a composite material composed of woven fiberglass cloth and an epoxy resin binder, for example, (2) multiple interconnection metal layers, made of copper, each having a thickness between 10 and 50 micrometers, between 25 and 50 micrometers, between 10 and 40 micrometers or between 10 and 20 micrometers and over or under the core layer of its ball-grid-array (BGA) substrate 510, 520 or 530, wherein each of the interconnection metal layers of its ball-grid-array (BGA) substrate 510, 520 or 530 over the core layer of its ball-grid-array (BGA) substrate 510, 520 or 530 may couple to any of the interconnection metal layers of its ball-grid-array (BGA) substrate 510, 520 or 530 under the core layer of its ball-grid-array (BGA) substrate 510, 520 or 530 through a through hole in the core layer of its ball-grid-array (BGA) substrate 510, 520 or 530, (3) multiple polymer layers, i.e., insulating dielectric layers, such as Ajinomoto build-up films (ABFs) or layers of bismaleimide-triazine (BT) resin, each having a thickness between 10 and 50 micrometers, between 15 and 40 micrometers or between 20 and 30 micrometers and over or under the core layer of its ball-grid-array (BGA) substrate 510, 520 or 530 and between neighboring two of the interconnection metal layers of its ball-grid-array (BGA) substrate 510, 520 or 530, wherein each of the Ajinomoto build-up films (ABFs) may be made of epoxy, phenol hardener, cyanate ester and thermosetting olefin, and (4) two solder masks 513, each made of a polymer layer or an insulating dielectric layer having a thickness between 10 and 50 micrometers, between 15 and 40 micrometers or between 20 and 30 micrometers, at the top and bottom of its ball-grid-array (BGA) substrate 510, 520 or 530 respectively to cover the topmost and bottommost ones of the interconnection metal layers of its ball-grid-array (BGA) substrate 510, 520 or 530 respectively. Each of the first and third internal interconnects 515 and 518 of its ball-grid-array (BGA) substrate 510 may be provided by each of the interconnection metal layers of its ball-grid-array (BGA) substrate 510 and each of the second internal interconnects 517 of its ball-grid-array (BGA) substrate 510 may be provided by one or more of the interconnection metal layers of its ball-grid-array (BGA) substrate 510. Each of the first bonding pads 512 of its ball-grid-array (BGA) substrate 510 may be provided by the topmost one of the interconnection metal layers of its ball-grid-array (BGA) substrate 510 and at a bottom of an opening in the top one of the two solder masks 513 of its ball-grid-array (BGA) substrate 510, and each of the openings in the top one of the two solder masks 513 of its ball-grid-array (BGA) substrate 510 may be vertically over one of the first bonding pads 512 of its ball-grid-array (BGA) substrate 510. Each of the second and third bonding pads 514 and 516 of its ball-grid-array (BGA) substrate 510 may be provided by the bottommost one of the interconnection metal layers of its ball-grid-array (BGA) substrate 510 and at a top of an opening in the bottom one of the two solder masks 513 of its ball-grid-array (BGA) substrate 510, and each of the openings in the bottom one of the two solder masks 513 of its ball-grid-array (BGA) substrate 510 may be vertically under one of the second and third bonding pads 514 and 516 of its ball-grid-array (BGA) substrate 510. Each of the internal interconnects 526 of its ball-grid-array (BGA) substrate 520 may be provided by each of the interconnection metal layers of its ball-grid-array (BGA) substrate 520. Each of the first bonding pads 522 of its ball-grid-array (BGA) substrate 520 may be provided by the topmost one of the interconnection metal layers of its ball-grid-array (BGA) substrate 520 and at a bottom of an opening in the top one of the two solder masks 513 of its ball-grid-array (BGA) substrate 520, and each of the openings in the top one of the two solder masks 513 of its ball-grid-array (BGA) substrate 520 may be vertically over one of the first bonding pads 522 of its ball-grid-array (BGA) substrate 520. Each of the second bonding pads 524 of its ball-grid-array (BGA) substrate 520 may be provided by the bottommost one of the interconnection metal layers of its ball-grid-array (BGA) substrate 520 and at a top of an opening in the bottom one of the two solder masks 513 of its ball-grid-array (BGA) substrate 520, and each of the openings in the bottom one of the two solder masks 513 of its ball-grid-array (BGA) substrate 520 may be vertically under one of the second bonding pads 524 of its ball-grid-array (BGA) substrate 520. Each of the internal interconnects 546 of its ball-grid-array (BGA) substrate 540 may be provided by each of the interconnection metal layers of its ball-grid-array (BGA) substrate 540. Each of the first bonding pads 542 of its ball-grid-array (BGA) substrate 540 may be provided by the bottommost one of the interconnection metal layers of its ball-grid-array (BGA) substrate 540 and at a top of an opening in the bottom one of the two solder masks 513 of its ball-grid-array (BGA) substrate 540, and each of the openings in the bottom one of the two solder masks 513 of its ball-grid-array (BGA) substrate 540 may be vertically under one of the first bonding pads 542 of its ball-grid-array (BGA) substrate 540. Each of the second bonding pads 544 of its ball-grid-array (BGA) substrate 540 may be provided by the topmost one of the interconnection metal layers of its ball-grid-array (BGA) substrate 540 and at a bottom of an opening in the top one of the two solder masks 513 of its ball-grid-array (BGA) substrate 540, and each of the openings in the top one of the two solder masks 513 of its ball-grid-array (BGA) substrate 540 may be vertically over one of the second bonding pads 544 of its ball-grid-array (BGA) substrate 540.

Referring to FIG. 6, for the sixth type of field-programmable multi-chip package 501, each of a first group of the metal bumps or pads 236 of the field-programmable-gate-array (FPGA) integrated-circuit (IC) chip 200 of its field-programmable chip package 460 may couple to any or either of the non-volatile memory (NVM) integrated-circuit (IC) chips 300 of its non-volatile memory (NVM) chip package 530 for signal transmission through, in sequence, each of the one or more interconnection metal layers 466 of the interconnection scheme 464 of its field-programmable chip package 460, one of a first group of the metal bumps 472 of its field-programmable chip package 460, one of the second group of the first bonding pads 512 of its interconnection substrate 510, one of the third internal interconnects 518 of its interconnection substrate 510, one of the second group of the second bonding pads 514 of its interconnection substrate 510, one of a first group of the metal bumps 534 of its non-volatile memory (NVM) chip package 530, one of a first group of the second bonding pads 544 of the interconnection substrate 540 of its non-volatile memory (NVM) chip package 530, one of a first group of the internal interconnects 546 of the interconnection substrate 540 of its non-volatile memory (NVM) chip package 530, one of a first group of the first bonding pads 542 of the interconnection substrate 540 of its non-volatile memory (NVM) chip package 530 and one of a first group of the wirebonded wires 560 of its non-volatile memory (NVM) chip package 530; each of a second group of the metal bumps or pads 236 of the field-programmable-gate-array (FPGA) integrated-circuit (IC) chip 200 of its field-programmable chip package 460 may couple to one of its metal bumps 532 for delivery of a voltage of power supply or ground reference or for signal transmission through, in sequence, each of the one or more interconnection metal layers 466 of the interconnection scheme 464 of its field-programmable chip package 460, one of a second group of the metal bumps 472 of its field-programmable chip package 460, one of the first group of the first bonding pads 512 of its interconnection substrate 510, one of the first internal interconnects 515 of its interconnection substrate 510, one of the third bonding pads 516 of its interconnection substrate 510, one of its metal bumps 540, one of the first bonding pads 522 of its interconnection substrate 520, one of the internal interconnects 526 of its interconnection substrate 520 and one of the second bonding pads 524 of its interconnection substrate 520; either or any of the non-volatile memory (NVM) integrated-circuit (IC) chips 300 of its non-volatile memory (NVM) chip package 530 may couple to another of its metal bumps 532 for delivery of a voltage of power supply or ground reference or for signal transmission through, in sequence, one of a second group of the wirebonded wires 560 of its non-volatile memory (NVM) chip package 530, one of a second group of the first bonding pads 542 of the interconnection substrate 540 of its non-volatile memory (NVM) chip package 530, one of a second group of the internal interconnects 546 of the interconnection substrate 540 of its non-volatile memory (NVM) chip package 530, one of a second group of the second bonding pads 544 of the interconnection substrate 540 of its non-volatile memory (NVM) chip package 530, one of a second group of the metal bumps 534 of its non-volatile memory (NVM) chip package 530, one of the first group of the second bonding pads 514 of its interconnection substrate 510, one of the second internal interconnects 517 of its interconnection substrate 510, another of the third bonding pads 516 of its interconnection substrate 510, another of its metal bumps 540, another of the first bonding pads 522 of its interconnection substrate 520, another of the internal interconnects 526 of its interconnection substrate 520 and another of the second bonding pads 524 of its interconnection substrate 520.

### Specification for Seventh Type of Field-Programmable Multi-Chip Package

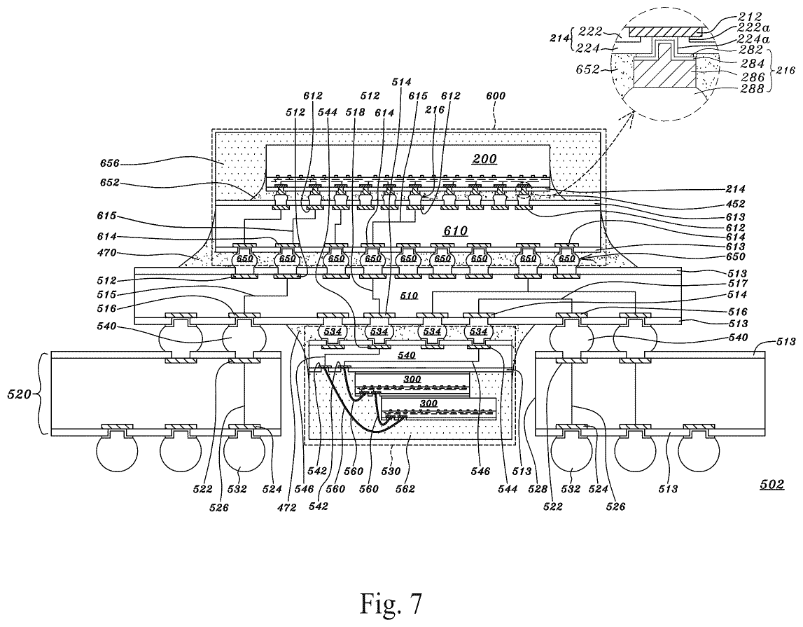

FIG. 7 is a cross-sectional view showing a seventh type of multi-chip package in accordance with an embodiment of the present application. Referring to FIG. 7, a seventh type of field-programmable multi-chip package 502 may be provided with a similar structure to the sixth type of multi-chip package 501 as illustrated in FIG. 6. For an element indicated by the same reference number shown in FIGS. 3, 5A, 5B, 6 and 7, the specification of the element as seen in FIG. 7 may be referred to that of the element as illustrated in FIGS. 3, 5A, 5B and 6. The difference therebetween is that the field-programmable chip package 600 of the sixth type of multi-chip package 501 as illustrated in FIG. 6 may be replaced with the field-programmable chip package 600 as illustrated in FIG. 5A or 5B to be assembled on the top of the interconnection substrate 510 for the seventh type of field-programmable multi-chip package 502 as seen in FIG. 7. For the seventh type of field-programmable multi-chip package 502, its field-programmable chip package 600, having the same specification as one illustrated in FIG. 5A or 5B, having the metal bumps 650 each having a bottom end bonded to one of the first bonding pads 512 of its interconnection substrate 510. Its underfill 470, such as polymer, may be between the bottom of the interconnection substrate 610 of its field-programmable chip package 600 and the top of its interconnection substrate 510 and covering a sidewall of each of the metal bumps 650 of its field-programmable chip package 600.

Referring to FIG. 7, for the seventh type of field-programmable multi-chip package 502, each of a first group of the metal bumps 216 of the field-programmable-gate-array (FPGA) integrated-circuit (IC) chip 200 of its field-programmable chip package 600 may couple to any or either of the non-volatile memory (NVM) integrated-circuit (IC) chips 300 of its non-volatile memory (NVM) chip package 530 for signal transmission through, in sequence, one of the first bonding pads 612 of the interconnection substrate 610 of its field-programmable chip package 600, one of the internal interconnects 615 of the interconnection substrate 610 of its field-programmable chip package 600, one of the second bonding pads 614 of the interconnection substrate 610 of its field-programmable chip package 600, one of the metal bumps 650 of its field-programmable chip package 600, one of the second group of the first bonding pads 512 of its interconnection substrate 510, one of the third internal interconnects 518 of its interconnection substrate 510, one of the second group of the second bonding pads 514 of its interconnection substrate 510, one of a first group of the metal bumps 534 of its non-volatile memory (NVM) chip package 530, one of a first group of the second bonding pads 544 of the interconnection substrate 540 of its non-volatile memory (NVM) chip package 530, one of a first group of the internal interconnects 546 of the interconnection substrate 540 of its non-volatile memory (NVM) chip package 530, one of a first group of the first bonding pads 542 of the interconnection substrate 540 of its non-volatile memory (NVM) chip package 530 and one of a first group of the wirebonded wires 560 of its non-volatile memory (NVM) chip package 530; each of a second group of the metal bumps 216 of the field-programmable-gate-array (FPGA) integrated-circuit (IC) chip 200 of its field-programmable chip package 600 may couple to one of its metal bumps 532 for delivery of a voltage of power supply or ground reference or for signal transmission through, in sequence, another of the first bonding pads 612 of the interconnection substrate 610 of its field-programmable chip package 600, another of the internal interconnects 615 of the interconnection substrate 610 of its field-programmable chip package 600, another of the second bonding pads 614 of the interconnection substrate 610 of its field-programmable chip package 600, another of the metal bumps 650 of its field-programmable chip package 600, one of the first group of the first bonding pads 512 of its interconnection substrate 510, one of the first internal interconnects 515 of its interconnection substrate 510, one of the third bonding pads 516 of its interconnection substrate 510, one of its metal bumps 540, one of the first bonding pads 522 of its interconnection substrate 520, one of the internal interconnects 526 of its interconnection substrate 520 and one of the second bonding pads 524 of its interconnection substrate 520; either or any of the non-volatile memory (NVM) integrated-circuit (IC) chips 300 of its non-volatile memory (NVM) chip package 530 may couple to another of its metal bumps 532 for delivery of a voltage of power supply or ground reference or for signal transmission through, in sequence, one of a second group of the wirebonded wires 560 of its non-volatile memory (NVM) chip package 530, one of a second group of the first bonding pads 542 of the interconnection substrate 540 of its non-volatile memory (NVM) chip package 530, one of a second group of the internal interconnects 546 of the interconnection substrate 540 of its non-volatile memory (NVM) chip package 530, one of a second group of the second bonding pads 544 of the interconnection substrate 540 of its non-volatile memory (NVM) chip package 530, one of a second group of the metal bumps 534 of its non-volatile memory (NVM) chip package 530, one of the first group of the second bonding pads 514 of its interconnection substrate 510, one of the second internal interconnects 517 of its interconnection substrate 510, another of the third bonding pads 516 of its interconnection substrate 510, another of its metal bumps 540, another of the first bonding pads 522 of its interconnection substrate 520, another of the internal interconnects 526 of its interconnection substrate 520 and another of the second bonding pads 524 of its interconnection substrate 520.

### Miscellaneous

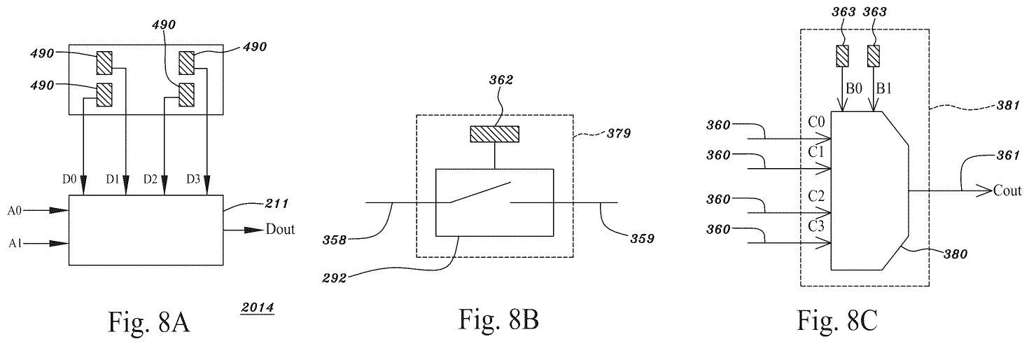

FIG. 8A is a schematic view showing a block diagram of a field-programmable or configurable logic cell or element or look-up table (LUT) in accordance with an embodiment of the present application. FIG. 8B is a circuit diagram illustrating a field-programmable or configurable switch in accordance with an embodiment of the present application. FIG. 8C is a circuit diagram illustrating a field-programmable or configurable selection circuit in accordance with an embodiment of the present application. Referring to FIGS. 1-4, 5A, 5B, 6 and 7, any of the field-programmable-gate-array (FPGA) integrated-circuit (IC) chip 200 of each type of the first and second types of field-programmable multi-chip packages 101 and 102 for the first alternative, the field-programmable-gate-array (FPGA) integrated-circuit (IC) chip 200 of each type of the third through seventh types of field-programmable multi-chip packages 401, 402, 403, 501 and 502 and the field-programmable-gate-array (FPGA) integrated-circuit (IC) chip 300 of each type of the first and second types of field-programmable multi-chip packages 101 and 102 for the second alternative may include one or more of the following field-programmable or configurable circuits:

(1) A field-programmable or configurable look-up table (LUT) 2014, as seen in FIG. 8A, may include a first group of static random-access memory (SRAM) cells 490 for storing the configuration data for the look-up table (LUT) 2014 therein and a first selection circuit 211, e.g., multiplexer, having a first input data set (A0, A1) for a logic operation for the look-up table (LUT) 2014 and a second input data set (D0, D1, D2, D3) having data associated with the configuration data for the look-up table (LUT) 2014, wherein the first selection circuit 211 is configured to select, in accordance with the first input data set (A0, A1) of the first selection circuit 211, input data from the second input data set (D0, D1, D2, D3) of the first selection circuit 211 as output data Dout of the first selection circuit 211 for the logic operation. Changing the configuration data stored in the first group of static random-access memory (SRAM) cells 490 may change a function of a logic circuit, i.e. a function of the (LUT) 2014.

(2) A field-programmable or configurable switch 379, as seen in FIG. 8B, may include a second static random-access memory (SRAM) cell 362 for storing the configuration data for controlling a pass/no-pass switch 292 of the field-programmable or configurable switch 379, and therefore for controlling pass/no-pass interconnection of its field-programmable-gate-array (FPGA) integrated-circuit (IC) chip 200. The pass/no-pass switch 292 has input data associated with the configuration data for pass/no-pass interconnection. Its field-programmable-gate-array (FPGA) integrated-circuit (IC) chip 200 may include an interconnection scheme therein having a first and second interconnect 358 and 359 coupling to the pass/no-pass switch 292, wherein the field-programmable or configurable switch 379 is configured to control, in accordance with the input data, coupling between the first and second interconnects 358 and 359. Changing the configuration data stored in the second static random-access memory (SRAM) cell 362 may change coupling between the first and second interconnects 358 and 359.

(3) A field-programmable or configurable selection circuit 381, as seen in FIG. 8C, may include a third group of static random-access memory (SRAM) cells 363 for storing the configuration data for selecting or multiplexing interconnection to select or multiplex interconnects of the interconnection scheme of its field-programmable-gate-array (FPGA) integrated-circuit (IC) chip 200, and a second selection circuit 380, e.g., multiplexer, having a first input data set (B0, B1) having data associated with the configuration data stored in the third group of static random-access memory (SRAM) cells 363, wherein the interconnection scheme of its field-programmable-gate-array (FPGA) integrated-circuit (IC) chip 200 may include multiple third interconnects 360 coupling to a second input data set (C0, C1, C2, C3) of the second selection circuit 380 and the second selection circuit 380 is configured to select, in accordance with the first input data set (B0, B1) of the second selection circuit 380, input data from the second input data set (C0, C1, C2, C3) of the second selection circuit 380 as output data Cout of the second selection circuit 380 to be passed to a fourth interconnect 361 of its field-programmable-gate-array (FPGA) integrated-circuit (IC) chip 200. Changing the configuration data stored in the third group of static random-access memory (SRAM) cells 363 may change coupling between any of the third interconnects 360 and the fourth interconnect 361.

Thereby, referring to FIGS. 1-4, 5A, 5B, 6, 7 and 8A-8C, for any type of the first and second types of field-programmable multi-chip packages 101 and 102 for the first alternative and the third through seventh types of field-programmable multi-chip packages 401, 402, 403, 501 and 502, its field-programmable-gate-array (FPGA) integrated-circuit (IC) chip 200 may comprise (1) the first group of static random-access memory (SRAM) cells 490 for configuring a logic circuit thereof, such as the field-programmable or configurable look-up table (LUT) 2014 thereof, for field programmable logic functions, wherein the function of the logic circuit thereof, i.e., the function of the field-programmable or configurable look-up table (LUT) 2014 thereof, may be altered or changed to another function by changing the configuration data stored in the first group of static random-access memory (SRAM) cells 490 thereof, (2) the second static random-access memory (SRAM) cell 362 for configuring the interconnection scheme thereof, such as the first and second interconnects 358 and 359 thereof, for field programmable interconnection, wherein the coupling between the interconnects 358 and 359 of the interconnection scheme thereof may be altered or changed by changing the configuration data stored in the second static random-access memory (SRAM) cell 362 thereof, and (3) the third group of static random-access memory (SRAM) cells 363 for configuring the interconnection scheme thereof, such as the multiple third interconnects 360 thereof and the fourth interconnect 361 thereof, for field programmable interconnection, wherein the coupling between any of the third interconnects 360 of the interconnection scheme thereof and the fourth interconnect 361 of the interconnection scheme 20 thereof may be altered or changed by changing the configuration data stored in the third group of static random-access memory (SRAM) cells 363 thereof.

Referring to FIGS. 1, 2 and 8A-8C, for each type of the first and second types of field-programmable multi-chip packages 101 and 102 for the second alternative, its field-programmable-gate-array (FPGA) integrated-circuit (IC) chip 300 may comprise (1) the first group of static random-access memory (SRAM) cells 490 for configuring a logic circuit thereof, such as the field-programmable or configurable look-up table (LUT) 2014 thereof, for field programmable logic functions, wherein the function of the logic circuit thereof, i.e., the function of the field-programmable or configurable look-up table (LUT) 2014 thereof, may be altered or changed to another function by changing the configuration data stored in the first group of static random-access memory (SRAM) cells 490 thereof, (2) the second static random-access memory (SRAM) cell 362 for configuring the interconnection scheme thereof, such as the first and second interconnects 358 and 359 thereof, for field programmable interconnection, wherein the coupling between the interconnects 358 and 359 of the interconnection scheme thereof may be altered or changed by changing the configuration data stored in the second static random-access memory (SRAM) cell 362 thereof, and (3) the third group of static random-access memory (SRAM) cells 363 for configuring the interconnection scheme thereof, such as the multiple third interconnects 360 thereof and the fourth interconnect 361 thereof, for field programmable interconnection, wherein the coupling between any of the third interconnects 360 of the interconnection scheme thereof and the fourth interconnect 361 of the interconnection scheme 20 thereof may be altered or changed by changing the configuration data stored in the third group of static random-access memory (SRAM) cells 363 thereof.

Referring to FIGS. 1, 2 and 8A-8C, for each type of the first and second types of field-programmable multi-chip packages 101 and 102 for the first alternative being powered on, its non-volatile memory (NVM) integrated-circuit (IC) chip 300 may include multiple non-volatile memory (NVM) cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be loaded and stored into the first group of static random-access memory (SRAM) cells 490 of its field-programmable-gate-array (FPGA) IC chip 200 through one or more of its third wirebonded wires 156, (2) storing therein the configuration data for pass/no-pass interconnection to be loaded and stored into the second static random-access memory (SRAM) cell 362 of its field-programmable-gate-array (FPGA) IC chip 200 through one or more of its third wirebonded wires 156, and (3) storing therein the configuration data for selecting or multiplexing interconnection to be loaded and stored into the third group of static random-access memory (SRAM) cell 363 of its field-programmable-gate-array (FPGA) IC chip 200 through one or more of its third wirebonded wires 156, for programming or configuring its field-programmable-gate-array (FPGA) integrated-circuit (IC) chip 200. Its non-volatile memory (NVM) integrated-circuit (IC) chip 300 may include the non-volatile memory (NVM) cells for storing therein operation data received from (1) the output data Dout of the first selection circuit 211 of the field-programmable or configurable look-up table (LUT) 2014 of its field-programmable-gate-array (FPGA) integrated-circuit (IC) chip 200, (2) the second interconnect 359 of the interconnection scheme of its field-programmable-gate-array (FPGA) integrated-circuit (IC) chip 200 and (3) the output data Cout of the second selection circuit 380 of its field-programmable-gate-array (FPGA) integrated-circuit (IC) chip 200, and to be passed (1) as the first input data set (A0, A1) of the first selection circuit 211 of the field-programmable or configurable look-up table (LUT) 2014 of its field-programmable-gate-array (FPGA) integrated-circuit (IC) chip 200, (2) to the first interconnect 358 of the interconnection scheme of its field-programmable-gate-array (FPGA) integrated-circuit (IC) chip 200 and (3) as the second input data set (C0, C1, C2, C3) of the second selection circuit 380 of its field-programmable-gate-array (FPGA) integrated-circuit (IC) chip 200.

Referring to FIGS. 1, 2 and 8A-8C, for each type of the first and second types of field-programmable multi-chip packages 101 and 102 for the first alternative to be powered off, its non-volatile memory (NVM) integrated-circuit (IC) chip 300 may include the non-volatile memory (NVM) cells for (1) storing therein the configuration data for the look-up table (LUT) 2014 to be backed up and received from the first group of static random-access memory (SRAM) cells 490 of its field-programmable-gate-array (FPGA) IC chip 200 through one or more of its third wirebonded wires 156, (2) storing therein the configuration data for pass/no-pass interconnection to be to be backed up and received from the second static random-access memory (SRAM) cell 362 of its field-programmable-gate-array (FPGA) IC chip 200 through one or more of its third wirebonded wires 156, and (3) storing therein the configuration data for selecting or multiplexing interconnection to be to be backed up and received from the third group of static random-access memory (SRAM) cell 363 of its field-programmable-gate-array (FPGA) IC chip 200 through one or more of its third wirebonded wires 156.

Referring to FIGS. 1, 2 and 8A-8C, for each type of the first and second types of field-programmable multi-chip packages 101 and 102 for the second alternative being powered on, its non-volatile memory (NVM) integrated-circuit (IC) chip 200 may include multiple non-volatile memory (NVM) cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be loaded and stored into the first group of static random-access memory (SRAM) cells 490 of its field-programmable-gate-array (FPGA) IC chip 300 through one or more of its third wirebonded wires 156, (2) storing therein the configuration data for pass/no-pass interconnection to be loaded and stored into the second static random-access memory (SRAM) cell 362 of its field-programmable-gate-array (FPGA) IC chip 300 through one or more of its third wirebonded wires 156, and (3) storing therein the configuration data for selecting or multiplexing interconnection to be loaded and stored into the third group of static random-access memory (SRAM) cell 363 of its field-programmable-gate-array (FPGA) IC chip 300 through one or more of its third wirebonded wires 156, for programming or configuring its field-programmable-gate-array (FPGA) integrated-circuit (IC) chip 300. Its non-volatile memory (NVM) integrated-circuit (IC) chip 200 may include the non-volatile memory (NVM) cells for storing therein operation data received from (1) the output data Dout of the first selection circuit 211 of the field-programmable or configurable look-up table (LUT) 2014 of its field-programmable-gate-array (FPGA) integrated-circuit (IC) chip 200, (2) the second interconnect 359 of the interconnection scheme of its field-programmable-gate-array (FPGA) integrated-circuit (IC) chip 200 and (3) the output data Cout of the second selection circuit 380 of its field-programmable-gate-array (FPGA) integrated-circuit (IC) chip 200, and to be passed (1) as the first input data set (A0, A1) of the first selection circuit 211 of the field-programmable or configurable look-up table (LUT) 2014 of its field-programmable-gate-array (FPGA) integrated-circuit (IC) chip 200, (2) to the first interconnect 358 of the interconnection scheme of its field-programmable-gate-array (FPGA) integrated-circuit (IC) chip 200 and (3) as the second input data set (C0, C1, C2, C3) of the second selection circuit 380 of its field-programmable-gate-array (FPGA) integrated-circuit (IC) chip 200.

Referring to FIGS. 1, 2 and 8A-8C, for each type of the first and second types of field-programmable multi-chip packages 101 and 102 for the second alternative to be powered off, its non-volatile memory (NVM) integrated-circuit (IC) chip 200 may include the non-volatile memory (NVM) cells for (1) storing therein the configuration data for the look-up table (LUT) 2014 to be backed up and received from the first group of static random-access memory (SRAM) cells 490 of its field-programmable-gate-array (FPGA) IC chip 300 through one or more of its third wirebonded wires 156, (2) storing therein the configuration data for pass/no-pass interconnection to be backed up and received from the second static random-access memory (SRAM) cell 362 of its field-programmable-gate-array (FPGA) IC chip 300 through one or more of its third wirebonded wires 156, and (3) storing therein the configuration data for selecting or multiplexing interconnection to be backed up and received from the third group of static random-access memory (SRAM) cell 363 of its field-programmable-gate-array (FPGA) IC chip 300 through one or more of its third wirebonded wires 156, for programming or configuring its field-programmable-gate-array (FPGA) integrated-circuit (IC) chip 300.

Referring to FIGS. 3 and 8A-8C, for the third type of field-programmable multi-chip package 401 being powered on, its non-volatile memory (NVM) integrated-circuit (IC) chip 300 may include multiple non-volatile memory (NVM) cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be loaded and stored into the first group of static random-access memory (SRAM) cells 490 of its field-programmable-gate-array (FPGA) IC chip 200 through, in sequence, one or more of its wirebonded wires 454, one or more of the second group of the second bonding pads 414 of its interconnection substrate 410, one or more of the third internal interconnects 418 of its interconnection substrate 410, one or more of the second group of the first bonding pads 412 of its interconnection substrate 410 and one or more of the first group of the metal bumps 216 of its field-programmable-gate-array (FPGA) integrated-circuit (IC) chip 200, (2) storing therein the configuration data for pass/no-pass interconnection to be loaded and stored into the second static random-access memory (SRAM) cell 362 of its field-programmable-gate-array (FPGA) IC chip 200 through, in sequence, one or more of its wirebonded wires 454, one or more of the second group of the second bonding pads 414 of its interconnection substrate 410, one or more of the third internal interconnects 418 of its interconnection substrate 410, one or more of the second group of the first bonding pads 412 of its interconnection substrate 410 and one or more of the first group of the metal bumps 216 of its field-programmable-gate-array (FPGA) integrated-circuit (IC) chip 200, and (3) storing therein the configuration data for selecting or multiplexing interconnection to be loaded and stored into the third group of static random-access memory (SRAM) cell 363 of its field-programmable-gate-array (FPGA) IC chip 200 through, in sequence, one or more of its wirebonded wires 454, one or more of the second group of the second bonding pads 414 of its interconnection substrate 410, one or more of the third internal interconnects 418 of its interconnection substrate 410, one or more of the second group of the first bonding pads 412 of its interconnection substrate 410 and one or more of the first group of the metal bumps 216 of its field-programmable-gate-array (FPGA) integrated-circuit (IC) chip 200, for programming or configuring its field-programmable-gate-array (FPGA) integrated-circuit (IC) chip 200. Its non-volatile memory (NVM) integrated-circuit (IC) chip 300 may include the non-volatile memory (NVM) cells for storing therein operation data received from (1) the output data Dout of the first selection circuit 211 of the field-programmable or configurable look-up table (LUT) 2014 of its field-programmable-gate-array (FPGA) integrated-circuit (IC) chip 200, (2) the second interconnect 359 of the interconnection scheme of its field-programmable-gate-array (FPGA) integrated-circuit (IC) chip 200 and (3) the output data Cout of the second selection circuit 380 of its field-programmable-gate-array (FPGA) integrated-circuit (IC) chip 200, and to be passed (1) as the first input data set (A0, A1) of the first selection circuit 211 of the field-programmable or configurable look-up table (LUT) 2014 of its field-programmable-gate-array (FPGA) integrated-circuit (IC) chip 200, (2) to the first interconnect 358 of the interconnection scheme of its field-programmable-gate-array (FPGA) integrated-circuit (IC) chip 200 and (3) as the second input data set (C0, C1, C2, C3) of the second selection circuit 380 of its field-programmable-gate-array (FPGA) integrated-circuit (IC) chip 200.

Referring to FIGS. 3 and 8A-8C, for the third type of field-programmable multi-chip package 401 to be powered off, its non-volatile memory (NVM) integrated-circuit (IC) chip 300 may include the non-volatile memory (NVM) cells for (1) storing therein the configuration data for the look-up table (LUT) 2014 to be backed up and received from the first group of static random-access memory (SRAM) cells 490 of its field-programmable-gate-array (FPGA) IC chip 200 through, in sequence, one or more of the first group of the metal bumps 216 of its field-programmable-gate-array (FPGA) integrated-circuit (IC) chip 200, one or more of the second group of the first bonding pads 412 of its interconnection substrate 410, one or more of the third internal interconnects 418 of its interconnection substrate 410, one or more of the second group of the second bonding pads 414 of its interconnection substrate 410 and one or more of its wirebonded wires 454, (2) storing therein the configuration data for pass/no-pass interconnection to be backed up and received from the second static random-access memory (SRAM) cell 362 of its field-programmable-gate-array (FPGA) IC chip 200 through, in sequence, one or more of the first group of the metal bumps 216 of its field-programmable-gate-array (FPGA) integrated-circuit (IC) chip 200, one or more of the second group of the first bonding pads 412 of its interconnection substrate 410, one or more of the third internal interconnects 418 of its interconnection substrate 410, one or more of the second group of the second bonding pads 414 of its interconnection substrate 410 and one or more of its wirebonded wires 454, and (3) storing therein the configuration data for selecting or multiplexing interconnection to be backed up and received from the third group of static random-access memory (SRAM) cell 363 of its field-programmable-gate-array (FPGA) IC chip 200 through, in sequence, one or more of the first group of the metal bumps 216 of its field-programmable-gate-array (FPGA) integrated-circuit (IC) chip 200, one or more of the second group of the first bonding pads 412 of its interconnection substrate 410, one or more of the third internal interconnects 418 of its interconnection substrate 410, one or more of the second group of the second bonding pads 414 of its interconnection substrate 410 and one or more of its wirebonded wires 454.

Referring to FIGS. 4 and 8A-8C, for the fourth type of field-programmable multi-chip package 402 being powered on, its non-volatile memory (NVM) integrated-circuit (IC) chip 300 may include multiple non-volatile memory (NVM) cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be loaded and stored into the first group of static random-access memory (SRAM) cells 490 of the field-programmable-gate-array (FPGA) IC chip 200 of its field-programmable chip package 460 through, in sequence, one or more of its wirebonded wires 454, one or more of the second group of the second bonding pads 414 of its interconnection substrate 410, one or more of the third internal interconnects 418 of its interconnection substrate 410, one or more of the second group of the first bonding pads 412 of its interconnection substrate 410, one or more of the metal bumps 472 of its field-programmable chip package 460, each of the one or more interconnection metal layers 466 of the interconnection scheme 464 of its field-programmable chip package 460 and one or more of the first group of the metal bumps or pads 236 of the field-programmable-gate-array (FPGA) integrated-circuit (IC) chip 200 of its field-programmable chip package 460, (2) storing therein the configuration data for pass/no-pass interconnection to be loaded and stored into the second static random-access memory (SRAM) cell 362 of the field-programmable-gate-array (FPGA) IC chip 200 of its field-programmable chip package 460 through, in sequence, one or more of its wirebonded wires 454, one or more of the second group of the second bonding pads 414 of its interconnection substrate 410, one or more of the third internal interconnects 418 of its interconnection substrate 410, one or more of the second group of the first bonding pads 412 of its interconnection substrate 410, one or more of the metal bumps 472 of its field-programmable chip package 460, each of the one or more interconnection metal layers 466 of the interconnection scheme 464 of its field-programmable chip package 460 and one or more of the first group of the metal bumps or pads 236 of the field-programmable-gate-array (FPGA) integrated-circuit (IC) chip 200 of its field-programmable chip package 460, and (3) storing therein the configuration data for selecting or multiplexing interconnection to be loaded and stored into the third group of static random-access memory (SRAM) cell 363 of the field-programmable-gate-array (FPGA) IC chip 200 of its field-programmable chip package 460 through, in sequence, one or more of its wirebonded wires 454, one or more of the second group of the second bonding pads 414 of its interconnection substrate 410, one or more of the third internal interconnects 418 of its interconnection substrate 410, one or more of the second group of the first bonding pads 412 of its interconnection substrate 410, one or more of the metal bumps 472 of its field-programmable chip package 460, each of the one or more interconnection metal layers 466 of the interconnection scheme 464 of its field-programmable chip package 460 and one or more of the first group of the metal bumps or pads 236 of the field-programmable-gate-array (FPGA) integrated-circuit (IC) chip 200 of its field-programmable chip package 460, for programming or configuring the field-programmable-gate-array (FPGA) integrated-circuit (IC) chip 200 of its field-programmable chip package 460. Its non-volatile memory (NVM) integrated-circuit (IC) chip 300 may include the non-volatile memory (NVM) cells for storing therein operation data received from (1) the output data Dout of the first selection circuit 211 of the field-programmable or configurable look-up table (LUT) 2014 of its field-programmable-gate-array (FPGA) integrated-circuit (IC) chip 200, (2) the second interconnect 359 of the interconnection scheme of its field-programmable-gate-array (FPGA) integrated-circuit (IC) chip 200 and (3) the output data Cout of the second selection circuit 380 of its field-programmable-gate-array (FPGA) integrated-circuit (IC) chip 200, and to be passed (1) as the first input data set (A0, A1) of the first selection circuit 211 of the field-programmable or configurable look-up table (LUT) 2014 of its field-programmable-gate-array (FPGA) integrated-circuit (IC) chip 200, (2) to the first interconnect 358 of the interconnection scheme of its field-programmable-gate-array (FPGA) integrated-circuit (IC) chip 200 and (3) as the second input data set (C0, C1, C2, C3) of the second selection circuit 380 of its field-programmable-gate-array (FPGA) integrated-circuit (IC) chip 200.

Referring to FIGS. 4 and 8A-8C, for the fourth type of field-programmable multi-chip package 402 to be powered off, its non-volatile memory (NVM) integrated-circuit (IC) chip 300 may include the non-volatile memory (NVM) cells for (1) storing therein the configuration data for the look-up table (LUT) 2014 to be backed up and received from the first group of static random-access memory (SRAM) cells 490 of the field-programmable-gate-array (FPGA) IC chip 200 of its field-programmable chip package 460 through, in sequence, one or more of the first group of the metal bumps or pads 236 of the field-programmable-gate-array (FPGA) integrated-circuit (IC) chip 200 of its field-programmable chip package 460, each of the one or more interconnection metal layers 466 of the interconnection scheme 464 of its field-programmable chip package 460, one or more of the metal bumps 472 of its field-programmable chip package 460, one or more of the second group of the first bonding pads 412 of its interconnection substrate 410, one or more of the third internal interconnects 418 of its interconnection substrate 410, one or more of the second group of the second bonding pads 414 of its interconnection substrate 410 and one or more of its wirebonded wires 454, (2) storing therein the configuration data for pass/no-pass interconnection to be backed up and received from the second static random-access memory (SRAM) cell 362 of the field-programmable-gate-array (FPGA) IC chip 200 of its field-programmable chip package 460 through, in sequence, one or more of the first group of the metal bumps or pads 236 of the field-programmable-gate-array (FPGA) integrated-circuit (IC) chip 200 of its field-programmable chip package 460, each of the one or more interconnection metal layers 466 of the interconnection scheme 464 of its field-programmable chip package 460, one or more of the metal bumps 472 of its field-programmable chip package 460, one or more of the second group of the first bonding pads 412 of its interconnection substrate 410, one or more of the third internal interconnects 418 of its interconnection substrate 410, one or more of the second group of the second bonding pads 414 of its interconnection substrate 410 and one or more of its wirebonded wires 454, and (3) storing therein the configuration data for selecting or multiplexing interconnection to be backed up and received from the third group of static random-access memory (SRAM) cell 363 of the field-programmable-gate-array (FPGA) IC chip 200 of its field-programmable chip package 460 through, in sequence, one or more of the first group of the metal bumps or pads 236 of the field-programmable-gate-array (FPGA) integrated-circuit (IC) chip 200 of its field-programmable chip package 460, each of the one or more interconnection metal layers 466 of the interconnection scheme 464 of its field-programmable chip package 460, one or more of the metal bumps 472 of its field-programmable chip package 460, one or more of the second group of the first bonding pads 412 of its interconnection substrate 410, one or more of the third internal interconnects 418 of its interconnection substrate 410, one or more of the second group of the second bonding pads 414 of its interconnection substrate 410 and one or more of its wirebonded wires 454.

Referring to FIGS. 5A and 5A and 8A-8C, for the fifth type of field-programmable multi-chip package 403 being powered on, its non-volatile memory (NVM) integrated-circuit (IC) chip 300 may include multiple non-volatile memory (NVM) cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be loaded and stored into the first group of static random-access memory (SRAM) cells 490 of the field-programmable-gate-array (FPGA) IC chip 200 of its field-programmable chip package 600 through, in sequence, one or more of its wirebonded wires 454, one or more of the second group of the second bonding pads 414 of its interconnection substrate 410, one or more of the third internal interconnects 418 of its interconnection substrate 410, one or more of the second group of the first bonding pads 412 of its interconnection substrate 410, one or more of the metal bumps 650 of its field-programmable chip package 600, one or more of the second bonding pads 614 of the interconnection substrate 610 of its field-programmable chip package 600, one or more of the internal interconnects 615 of the interconnection substrate 610 of its field-programmable chip package 600, one or more of the first bonding pads 612 of the interconnection substrate 610 of its field-programmable chip package 600 and one or more of the first group of the metal bumps 216 of the field-programmable-gate-array (FPGA) integrated-circuit (IC) chip 200 of its field-programmable chip package 600, (2) storing therein the configuration data for pass/no-pass interconnection to be loaded and stored into the second static random-access memory (SRAM) cell 362 of the field-programmable-gate-array (FPGA) IC chip 200 of its field-programmable chip package 600 through, in sequence, one or more of its wirebonded wires 454, one or more of the second group of the second bonding pads 414 of its interconnection substrate 410, one or more of the third internal interconnects 418 of its interconnection substrate 410, one or more of the second group of the first bonding pads 412 of its interconnection substrate 410, one or more of the metal bumps 650 of its field-programmable chip package 600, one or more of the second bonding pads 614 of the interconnection substrate 610 of its field-programmable chip package 600, one or more of the internal interconnects 615 of the interconnection substrate 610 of its field-programmable chip package 600, one or more of the first bonding pads 612 of the interconnection substrate 610 of its field-programmable chip package 600 and one or more of the first group of the metal bumps 216 of the field-programmable-gate-array (FPGA) integrated-circuit (IC) chip 200 of its field-programmable chip package 600, and (3) storing therein the configuration data for selecting or multiplexing interconnection to be loaded and stored into the third group of static random-access memory (SRAM) cell 363 of the field-programmable-gate-array (FPGA) IC chip 200 of its field-programmable chip package 600 through, in sequence, one or more of its wirebonded wires 454, one or more of the second group of the second bonding pads 414 of its interconnection substrate 410, one or more of the third internal interconnects 418 of its interconnection substrate 410, one or more of the second group of the first bonding pads 412 of its interconnection substrate 410, one or more of the metal bumps 650 of its field-programmable chip package 600, one or more of the second bonding pads 614 of the interconnection substrate 610 of its field-programmable chip package 600, one or more of the internal interconnects 615 of the interconnection substrate 610 of its field-programmable chip package 600, one or more of the first bonding pads 612 of the interconnection substrate 610 of its field-programmable chip package 600 and one or more of the first group of the metal bumps 216 of the field-programmable-gate-array (FPGA) integrated-circuit (IC) chip 200 of its field-programmable chip package 600, for programming or configuring the field-programmable-gate-array (FPGA) integrated-circuit (IC) chip 200 of its field-programmable chip package 600. Its non-volatile memory (NVM) integrated-circuit (IC) chip 300 may include the non-volatile memory (NVM) cells for storing therein operation data received from (1) the output data Dout of the first selection circuit 211 of the field-programmable or configurable look-up table (LUT) 2014 of its field-programmable-gate-array (FPGA) integrated-circuit (IC) chip 200, (2) the second interconnect 359 of the interconnection scheme of its field-programmable-gate-array (FPGA) integrated-circuit (IC) chip 200 and (3) the output data Cout of the second selection circuit 380 of its field-programmable-gate-array (FPGA) integrated-circuit (IC) chip 200, and to be passed (1) as the first input data set (A0, A1) of the first selection circuit 211 of the field-programmable or configurable look-up table (LUT) 2014 of its field-programmable-gate-array (FPGA) integrated-circuit (IC) chip 200, (2) to the first interconnect 358 of the interconnection scheme of its field-programmable-gate-array (FPGA) integrated-circuit (IC) chip 200 and (3) as the second input data set (C0, C1, C2, C3) of the second selection circuit 380 of its field-programmable-gate-array (FPGA) integrated-circuit (IC) chip 200.

Referring to FIGS. 5A and 5A and 8A-8C, for the fifth type of field-programmable multi-chip package 403 to be powered off, its non-volatile memory (NVM) integrated-circuit (IC) chip 300 may include the non-volatile memory (NVM) cells for (1) storing therein the configuration data for the look-up table (LUT) 2014 to be backed up and received from the first group of static random-access memory (SRAM) cells 490 of the field-programmable-gate-array (FPGA) IC chip 200 of its field-programmable chip package 600 through, in sequence, one or more of the first group of the metal bumps 216 of the field-programmable-gate-array (FPGA) integrated-circuit (IC) chip 200 of its field-programmable chip package 600, one or more of the first bonding pads 612 of the interconnection substrate 610 of its field-programmable chip package 600, one or more of the internal interconnects 615 of the interconnection substrate 610 of its field-programmable chip package 600, one or more of the second bonding pads 614 of the interconnection substrate 610 of its field-programmable chip package 600, one or more of the metal bumps 650 of its field-programmable chip package 600, one or more of the second group of the first bonding pads 412 of its interconnection substrate 410, one or more of the third internal interconnects 418 of its interconnection substrate 410, one or more of the second group of the second bonding pads 414 of its interconnection substrate 410 and one or more of its wirebonded wires 454, (2) storing therein the configuration data for pass/no-pass interconnection to be backed up and received from the second static random-access memory (SRAM) cell 362 of the field-programmable-gate-array (FPGA) IC chip 200 of its field-programmable chip package 600 through, in sequence, one or more of the first group of the metal bumps 216 of the field-programmable-gate-array (FPGA) integrated-circuit (IC) chip 200 of its field-programmable chip package 600, one or more of the first bonding pads 612 of the interconnection substrate 610 of its field-programmable chip package 600, one or more of the internal interconnects 615 of the interconnection substrate 610 of its field-programmable chip package 600, one or more of the second bonding pads 614 of the interconnection substrate 610 of its field-programmable chip package 600, one or more of the metal bumps 650 of its field-programmable chip package 600, one or more of the second group of the first bonding pads 412 of its interconnection substrate 410, one or more of the third internal interconnects 418 of its interconnection substrate 410, one or more of the second group of the second bonding pads 414 of its interconnection substrate 410 and one or more of its wirebonded wires 454, and (3) storing therein the configuration data for selecting or multiplexing interconnection to be backed up and received from the third group of static random-access memory (SRAM) cell 363 of the field-programmable-gate-array (FPGA) IC chip 200 of its field-programmable chip package 600 through, in sequence, one or more of the first group of the metal bumps 216 of the field-programmable-gate-array (FPGA) integrated-circuit (IC) chip 200 of its field-programmable chip package 600, one or more of the first bonding pads 612 of the interconnection substrate 610 of its field-programmable chip package 600, one or more of the internal interconnects 615 of the interconnection substrate 610 of its field-programmable chip package 600, one or more of the second bonding pads 614 of the interconnection substrate 610 of its field-programmable chip package 600, one or more of the metal bumps 650 of its field-programmable chip package 600, one or more of the second group of the first bonding pads 412 of its interconnection substrate 410, one or more of the third internal interconnects 418 of its interconnection substrate 410, one or more of the second group of the second bonding pads 414 of its interconnection substrate 410 and one or more of its wirebonded wires 454.

Referring to FIGS. 6 and 8A-8C, for the sixth type of field-programmable multi-chip package 501 being powered on, each of the non-volatile memory (NVM) integrated-circuit (IC) chips 300 of its non-volatile memory (NVM) chip package 530 may include multiple non-volatile memory (NVM) cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be loaded and stored into the first group of static random-access memory (SRAM) cells 490 of the field-programmable-gate-array (FPGA) IC chip 200 of its field-programmable chip package 460 through, in sequence, one or more of the first group of the wirebonded wires 560 of its non-volatile memory (NVM) chip package 530, one or more of the first group of the first bonding pads 542 of the interconnection substrate 540 of its non-volatile memory (NVM) chip package 530, one or more of the first group of the internal interconnects 546 of the interconnection substrate 540 of its non-volatile memory (NVM) chip package 530, one or more of the first group of the second bonding pads 544 of the interconnection substrate 540 of its non-volatile memory (NVM) chip package 530, one or more of the first group of the metal bumps 534 of its non-volatile memory (NVM) chip package 530, one or more of the second group of the second bonding pads 514 of its interconnection substrate 510, one or more of the third internal interconnects 518 of its interconnection substrate 510, one or more of the second group of the first bonding pads 512 of its interconnection substrate 510, one or more of the first group of the metal bumps 472 of its field-programmable chip package 460, each of the one or more interconnection metal layers 466 of the interconnection scheme 464 of its field-programmable chip package 460 and one or more of the first group of the metal bumps or pads 236 of the field-programmable-gate-array (FPGA) integrated-circuit (IC) chip 200 of its field-programmable chip package 460, (2) storing therein the configuration data for pass/no-pass interconnection to be loaded and stored into the second static random-access memory (SRAM) cell 362 of the field-programmable-gate-array (FPGA) IC chip 200 of its field-programmable chip package 460 through, in sequence, one or more of the first group of the wirebonded wires 560 of its non-volatile memory (NVM) chip package 530, one or more of the first group of the first bonding pads 542 of the interconnection substrate 540 of its non-volatile memory (NVM) chip package 530, one or more of the first group of the internal interconnects 546 of the interconnection substrate 540 of its non-volatile memory (NVM) chip package 530, one or more of the first group of the second bonding pads 544 of the interconnection substrate 540 of its non-volatile memory (NVM) chip package 530, one or more of the first group of the metal bumps 534 of its non-volatile memory (NVM) chip package 530, one or more of the second group of the second bonding pads 514 of its interconnection substrate 510, one or more of the third internal interconnects 518 of its interconnection substrate 510, one or more of the second group of the first bonding pads 512 of its interconnection substrate 510, one or more of the first group of the metal bumps 472 of its field-programmable chip package 460, each of the one or more interconnection metal layers 466 of the interconnection scheme 464 of its field-programmable chip package 460 and one or more of the first group of the metal bumps or pads 236 of the field-programmable-gate-array (FPGA) integrated-circuit (IC) chip 200 of its field-programmable chip package 460, and (3) storing therein the configuration data for selecting or multiplexing interconnection to be loaded and stored into the third group of static random-access memory (SRAM) cell 363 of the field-programmable-gate-array (FPGA) IC chip 200 of its field-programmable chip package 460 through, in sequence, one or more of the first group of the wirebonded wires 560 of its non-volatile memory (NVM) chip package 530, one or more of the first group of the first bonding pads 542 of the interconnection substrate 540 of its non-volatile memory (NVM) chip package 530, one or more of the first group of the internal interconnects 546 of the interconnection substrate 540 of its non-volatile memory (NVM) chip package 530, one or more of the first group of the second bonding pads 544 of the interconnection substrate 540 of its non-volatile memory (NVM) chip package 530, one or more of the first group of the metal bumps 534 of its non-volatile memory (NVM) chip package 530, one or more of the second group of the second bonding pads 514 of its interconnection substrate 510, one or more of the third internal interconnects 518 of its interconnection substrate 510, one or more of the second group of the first bonding pads 512 of its interconnection substrate 510, one or more of the first group of the metal bumps 472 of its field-programmable chip package 460, each of the one or more interconnection metal layers 466 of the interconnection scheme 464 of its field-programmable chip package 460 and one or more of the first group of the metal bumps or pads 236 of the field-programmable-gate-array (FPGA) integrated-circuit (IC) chip 200 of its field-programmable chip package 460, for programming or configuring the field-programmable-gate-array (FPGA) integrated-circuit (IC) chip 200 of its field-programmable chip package 460. Each of the non-volatile memory (NVM) integrated-circuit (IC) chips 300 of its non-volatile memory (NVM) chip package 530 may include the non-volatile memory (NVM) cells for storing therein operation data received from (1) the output data Dout of the first selection circuit 211 of the field-programmable or configurable look-up table (LUT) 2014 of its field-programmable-gate-array (FPGA) integrated-circuit (IC) chip 200, (2) the second interconnect 359 of the interconnection scheme of its field-programmable-gate-array (FPGA) integrated-circuit (IC) chip 200 and (3) the output data Cout of the second selection circuit 380 of its field-programmable-gate-array (FPGA) integrated-circuit (IC) chip 200, and to be passed (1) as the first input data set (A0, A1) of the first selection circuit 211 of the field-programmable or configurable look-up table (LUT) 2014 of its field-programmable-gate-array (FPGA) integrated-circuit (IC) chip 200, (2) to the first interconnect 358 of the interconnection scheme of its field-programmable-gate-array (FPGA) integrated-circuit (IC) chip 200 and (3) as the second input data set (C0, C1, C2, C3) of the second selection circuit 380 of its field-programmable-gate-array (FPGA) integrated-circuit (IC) chip 200.

Referring to FIGS. 6 and 8A-8C, for the sixth type of field-programmable multi-chip package 501 to be powered off, each of the non-volatile memory (NVM) integrated-circuit (IC) chips 300 of its non-volatile memory (NVM) chip package 530 may include the non-volatile memory (NVM) cells for (1) storing therein the configuration data for the look-up table (LUT) 2014 to be backed up and received from the first group of static random-access memory (SRAM) cells 490 of the field-programmable-gate-array (FPGA) IC chip 200 of its field-programmable chip package 460 through, in sequence, one or more of the first group of the metal bumps or pads 236 of the field-programmable-gate-array (FPGA) integrated-circuit (IC) chip 200 of its field-programmable chip package 460, each of the one or more interconnection metal layers 466 of the interconnection scheme 464 of its field-programmable chip package 460, one or more of the first group of the metal bumps 472 of its field-programmable chip package 460, one or more of the second group of the first bonding pads 512 of its interconnection substrate 510, one or more of the third internal interconnects 518 of its interconnection substrate 510, one or more of the second group of the second bonding pads 514 of its interconnection substrate 510, one or more of the first group of the metal bumps 534 of its non-volatile memory (NVM) chip package 530, one or more of the first group of the second bonding pads 544 of the interconnection substrate 540 of its non-volatile memory (NVM) chip package 530, one or more of the first group of the internal interconnects 546 of the interconnection substrate 540 of its non-volatile memory (NVM) chip package 530, one or more of the first group of the first bonding pads 542 of the interconnection substrate 540 of its non-volatile memory (NVM) chip package 530 and one or more of the first group of the wirebonded wires 560 of its non-volatile memory (NVM) chip package 530, (2) storing therein the configuration data for pass/no-pass interconnection to be backed up and received from the second static random-access memory (SRAM) cell 362 of the field-programmable-gate-array (FPGA) IC chip 200 of its field-programmable chip package 460 through, in sequence, one or more of the first group of the metal bumps or pads 236 of the field-programmable-gate-array (FPGA) integrated-circuit (IC) chip 200 of its field-programmable chip package 460, each of the one or more interconnection metal layers 466 of the interconnection scheme 464 of its field-programmable chip package 460, one or more of the first group of the metal bumps 472 of its field-programmable chip package 460, one or more of the second group of the first bonding pads 512 of its interconnection substrate 510, one or more of the third internal interconnects 518 of its interconnection substrate 510, one or more of the second group of the second bonding pads 514 of its interconnection substrate 510, one or more of the first group of the metal bumps 534 of its non-volatile memory (NVM) chip package 530, one or more of the first group of the second bonding pads 544 of the interconnection substrate 540 of its non-volatile memory (NVM) chip package 530, one or more of the first group of the internal interconnects 546 of the interconnection substrate 540 of its non-volatile memory (NVM) chip package 530, one or more of the first group of the first bonding pads 542 of the interconnection substrate 540 of its non-volatile memory (NVM) chip package 530 and one or more of the first group of the wirebonded wires 560 of its non-volatile memory (NVM) chip package 530, and (3) storing therein the configuration data for selecting or multiplexing interconnection to be backed up and received from the third group of static random-access memory (SRAM) cell 363 of the field-programmable-gate-array (FPGA) IC chip 200 of its field-programmable chip package 460 through, in sequence, one or more of the first group of the metal bumps or pads 236 of the field-programmable-gate-array (FPGA) integrated-circuit (IC) chip 200 of its field-programmable chip package 460, each of the one or more interconnection metal layers 466 of the interconnection scheme 464 of its field-programmable chip package 460, one or more of the first group of the metal bumps 472 of its field-programmable chip package 460, one or more of the second group of the first bonding pads 512 of its interconnection substrate 510, one or more of the third internal interconnects 518 of its interconnection substrate 510, one or more of the second group of the second bonding pads 514 of its interconnection substrate 510, one or more of the first group of the metal bumps 534 of its non-volatile memory (NVM) chip package 530, one or more of the first group of the second bonding pads 544 of the interconnection substrate 540 of its non-volatile memory (NVM) chip package 530, one or more of the first group of the internal interconnects 546 of the interconnection substrate 540 of its non-volatile memory (NVM) chip package 530, one or more of the first group of the first bonding pads 542 of the interconnection substrate 540 of its non-volatile memory (NVM) chip package 530 and one or more of the first group of the wirebonded wires 560 of its non-volatile memory (NVM) chip package 530.

Referring to FIGS. 7 and 8A-8C, for the seventh type of field-programmable multi-chip package 502 being powered on, each of the non-volatile memory (NVM) integrated-circuit (IC) chips 300 of its non-volatile memory (NVM) chip package 530 may include multiple non-volatile memory (NVM) cells, such as NAND memory cells, NOR memory cells, resistive-random-access-memory (RRAM) cells, magnetoresistive-random-access-memory (MRAM) cells, ferroelectric-random-access-memory (FRAM) cells or phase-change-random-access-memory (PCM) cells, for (1) storing therein the configuration data for the look-up table (LUT) 2014 to be loaded and stored into the first group of static random-access memory (SRAM) cells 490 of the field-programmable-gate-array (FPGA) IC chip 200 of its field-programmable chip package 600 through, in sequence, one or more of the first group of the wirebonded wires 560 of its non-volatile memory (NVM) chip package 530, one or more of the first group of the first bonding pads 542 of the interconnection substrate 540 of its non-volatile memory (NVM) chip package 530, one or more of the first group of the internal interconnects 546 of the interconnection substrate 540 of its non-volatile memory (NVM) chip package 530, one or more of the first group of the second bonding pads 544 of the interconnection substrate 540 of its non-volatile memory (NVM) chip package 530, one or more of the first group of the metal bumps 534 of its non-volatile memory (NVM) chip package 530, one or more of the second group of the second bonding pads 514 of its interconnection substrate 510, one or more of the third internal interconnects 518 of its interconnection substrate 510, one or more of the second group of the first bonding pads 512 of its interconnection substrate 510, one or more of the metal bumps 650 of its field-programmable chip package 600, one or more of the second bonding pads 614 of the interconnection substrate 610 of its field-programmable chip package 600, one or more of the internal interconnects 615 of the interconnection substrate 610 of its field-programmable chip package 600, one or more of the first bonding pads 612 of the interconnection substrate 610 of its field-programmable chip package 600 and one or more of the first group of the metal bumps 216 of the field-programmable-gate-array (FPGA) integrated-circuit (IC) chip 200 of its field-programmable chip package 600, (2) storing therein the configuration data for pass/no-pass interconnection to be loaded and stored into the second static random-access memory (SRAM) cell 362 of the field-programmable-gate-array (FPGA) IC chip 200 of its field-programmable chip package 600 through, in sequence, one or more of the first group of the wirebonded wires 560 of its non-volatile memory (NVM) chip package 530, one or more of the first group of the first bonding pads 542 of the interconnection substrate 540 of its non-volatile memory (NVM) chip package 530, one or more of the first group of the internal interconnects 546 of the interconnection substrate 540 of its non-volatile memory (NVM) chip package 530, one or more of the first group of the second bonding pads 544 of the interconnection substrate 540 of its non-volatile memory (NVM) chip package 530, one or more of the first group of the metal bumps 534 of its non-volatile memory (NVM) chip package 530, one or more of the second group of the second bonding pads 514 of its interconnection substrate 510, one or more of the third internal interconnects 518 of its interconnection substrate 510, one or more of the second group of the first bonding pads 512 of its interconnection substrate 510, one or more of the metal bumps 650 of its field-programmable chip package 600, one or more of the second bonding pads 614 of the interconnection substrate 610 of its field-programmable chip package 600, one or more of the internal interconnects 615 of the interconnection substrate 610 of its field-programmable chip package 600, one or more of the first bonding pads 612 of the interconnection substrate 610 of its field-programmable chip package 600 and one or more of the first group of the metal bumps 216 of the field-programmable-gate-array (FPGA) integrated-circuit (IC) chip 200 of its field-programmable chip package 600, and (3) storing therein the configuration data for selecting or multiplexing interconnection to be loaded and stored into the third group of static random-access memory (SRAM) cell 363 of the field-programmable-gate-array (FPGA) IC chip 200 of its field-programmable chip package 600 through, in sequence, one or more of the first group of the wirebonded wires 560 of its non-volatile memory (NVM) chip package 530, one or more of the first group of the first bonding pads 542 of the interconnection substrate 540 of its non-volatile memory (NVM) chip package 530, one or more of the first group of the internal interconnects 546 of the interconnection substrate 540 of its non-volatile memory (NVM) chip package 530, one or more of the first group of the second bonding pads 544 of the interconnection substrate 540 of its non-volatile memory (NVM) chip package 530, one or more of the first group of the metal bumps 534 of its non-volatile memory (NVM) chip package 530, one or more of the second group of the second bonding pads 514 of its interconnection substrate 510, one or more of the third internal interconnects 518 of its interconnection substrate 510, one or more of the second group of the first bonding pads 512 of its interconnection substrate 510, one or more of the metal bumps 650 of its field-programmable chip package 600, one or more of the second bonding pads 614 of the interconnection substrate 610 of its field-programmable chip package 600, one or more of the internal interconnects 615 of the interconnection substrate 610 of its field-programmable chip package 600, one or more of the first bonding pads 612 of the interconnection substrate 610 of its field-programmable chip package 600 and one or more of the first group of the metal bumps 216 of the field-programmable-gate-array (FPGA) integrated-circuit (IC) chip 200 of its field-programmable chip package 600, for programming or configuring the field-programmable-gate-array (FPGA) integrated-circuit (IC) chip 200 of its field-programmable chip package 460. Each of the non-volatile memory (NVM) integrated-circuit (IC) chips 300 of its non-volatile memory (NVM) chip package 530 may include the non-volatile memory (NVM) cells for storing therein operation data received from (1) the output data Dout of the first selection circuit 211 of the field-programmable or configurable look-up table (LUT) 2014 of its field-programmable-gate-array (FPGA) integrated-circuit (IC) chip 200, (2) the second interconnect 359 of the interconnection scheme of its field-programmable-gate-array (FPGA) integrated-circuit (IC) chip 200 and (3) the output data Cout of the second selection circuit 380 of its field-programmable-gate-array (FPGA) integrated-circuit (IC) chip 200, and to be passed (1) as the first input data set (A0, A1) of the first selection circuit 211 of the field-programmable or configurable look-up table (LUT) 2014 of its field-programmable-gate-array (FPGA) integrated-circuit (IC) chip 200, (2) to the first interconnect 358 of the interconnection scheme of its field-programmable-gate-array (FPGA) integrated-circuit (IC) chip 200 and (3) as the second input data set (C0, C1, C2, C3) of the second selection circuit 380 of its field-programmable-gate-array (FPGA) integrated-circuit (IC) chip 200.

Referring to FIGS. 7 and 8A-8C, for the seventh type of field-programmable multi-chip package 502 to be powered off, each of the non-volatile memory (NVM) integrated-circuit (IC) chips 300 of its non-volatile memory (NVM) chip package 530 may include the non-volatile memory (NVM) cells for (1) storing therein the configuration data for the look-up table (LUT) 2014 to be backed up and received from the first group of static random-access memory (SRAM) cells 490 of the field-programmable-gate-array (FPGA) IC chip 200 of its field-programmable chip package 600 through, in sequence, one or more of the first group of the metal bumps 216 of the field-programmable-gate-array (FPGA) integrated-circuit (IC) chip 200 of its field-programmable chip package 600, one or more of the first bonding pads 612 of the interconnection substrate 610 of its field-programmable chip package 600, one or more of the internal interconnects 615 of the interconnection substrate 610 of its field-programmable chip package 600, one or more of the second bonding pads 614 of the interconnection substrate 610 of its field-programmable chip package 600, one or more of the metal bumps 650 of its field-programmable chip package 600, one or more of the second group of the first bonding pads 512 of its interconnection substrate 510, one or more of the third internal interconnects 518 of its interconnection substrate 510, one or more of the second group of the second bonding pads 514 of its interconnection substrate 510, one or more of the first group of the metal bumps 534 of its non-volatile memory (NVM) chip package 530, one or more of the first group of the second bonding pads 544 of the interconnection substrate 540 of its non-volatile memory (NVM) chip package 530, one or more of the first group of the internal interconnects 546 of the interconnection substrate 540 of its non-volatile memory (NVM) chip package 530, one or more of the first group of the first bonding pads 542 of the interconnection substrate 540 of its non-volatile memory (NVM) chip package 530 and one or more of the first group of the wirebonded wires 560 of its non-volatile memory (NVM) chip package 530, (2) storing therein the configuration data for pass/no-pass interconnection to be backed up and received from the second static random-access memory (SRAM) cell 362 of the field-programmable-gate-array (FPGA) IC chip 200 of its field-programmable chip package 600 through, in sequence, one or more of the first group of the metal bumps 216 of the field-programmable-gate-array (FPGA) integrated-circuit (IC) chip 200 of its field-programmable chip package 600, one or more of the first bonding pads 612 of the interconnection substrate 610 of its field-programmable chip package 600, one or more of the internal interconnects 615 of the interconnection substrate 610 of its field-programmable chip package 600, one or more of the second bonding pads 614 of the interconnection substrate 610 of its field-programmable chip package 600, one or more of the metal bumps 650 of its field-programmable chip package 600, one or more of the second group of the first bonding pads 512 of its interconnection substrate 510, one or more of the third internal interconnects 518 of its interconnection substrate 510, one or more of the second group of the second bonding pads 514 of its interconnection substrate 510, one or more of the first group of the metal bumps 534 of its non-volatile memory (NVM) chip package 530, one or more of the first group of the second bonding pads 544 of the interconnection substrate 540 of its non-volatile memory (NVM) chip package 530, one or more of the first group of the internal interconnects 546 of the interconnection substrate 540 of its non-volatile memory (NVM) chip package 530, one or more of the first group of the first bonding pads 542 of the interconnection substrate 540 of its non-volatile memory (NVM) chip package 530 and one or more of the first group of the wirebonded wires 560 of its non-volatile memory (NVM) chip package 530, and (3) storing therein the configuration data for selecting or multiplexing interconnection to be backed up and received from the third group of static random-access memory (SRAM) cell 363 of the field-programmable-gate-array (FPGA) IC chip 200 of its field-programmable chip package 600 through, in sequence, one or more of the first group of the metal bumps 216 of the field-programmable-gate-array (FPGA) integrated-circuit (IC) chip 200 of its field-programmable chip package 600, one or more of the first bonding pads 612 of the interconnection substrate 610 of its field-programmable chip package 600, one or more of the internal interconnects 615 of the interconnection substrate 610 of its field-programmable chip package 600, one or more of the second bonding pads 614 of the interconnection substrate 610 of its field-programmable chip package 600, one or more of the metal bumps 650 of its field-programmable chip package 600, one or more of the second group of the first bonding pads 512 of its interconnection substrate 510, one or more of the third internal interconnects 518 of its interconnection substrate 510, one or more of the second group of the second bonding pads 514 of its interconnection substrate 510, one or more of the first group of the metal bumps 534 of its non-volatile memory (NVM) chip package 530, one or more of the first group of the second bonding pads 544 of the interconnection substrate 540 of its non-volatile memory (NVM) chip package 530, one or more of the first group of the internal interconnects 546 of the interconnection substrate 540 of its non-volatile memory (NVM) chip package 530, one or more of the first group of the first bonding pads 542 of the interconnection substrate 540 of its non-volatile memory (NVM) chip package 530 and one or more of the first group of the wirebonded wires 560 of its non-volatile memory (NVM) chip package 530.

Alternatively, referring to FIGS. 1-4, 5A, 5B, 6, 7 and 8A-8C, for any type of the first and second types of field-programmable multi-chip packages 101 and 102 for the first alternative and the third through seventh types of field-programmable multi-chip packages 401, 402, 403, 501 and 502, its field-programmable-gate-array (FPGA) integrated-circuit (IC) chip 200 may be replaced with an embedded field-programmable-gate-array (eFPGA) IC chip, application-specific integrated-circuit (ASIC) chip, system-on-chip (SoC) chip, graphic-processing-unit (GPU) IC chip, central-processing-unit (CPU) IC chip, neural-network-processing-unit (NPU) IC chip, digital-signal-processing (DSP) IC chip, microcontroller-unit (MCU) IC chip, programmable-logic-device (PLD) IC chip or complex-programmable-logic-device (CPLD) IC chip comprising the field-programmable or configurable circuits as mentioned above.

Alternatively, referring to FIGS. 1, 2 and 8A-8C, for each type of the first and second types of field-programmable multi-chip packages 101 and 102 for the second alternative, its field-programmable-gate-array (FPGA) integrated-circuit (IC) chip 300 may be replaced with an embedded field-programmable-gate-array (eFPGA) IC chip, application-specific integrated-circuit (ASIC) chip, system-on-chip (SoC) chip, graphic-processing-unit (GPU) IC chip, central-processing-unit (CPU) IC chip, neural-network-processing-unit (NPU) IC chip, digital-signal-processing (DSP) IC chip, microcontroller-unit (MCU) IC chip, programmable-logic-device (PLD) IC chip or complex-programmable-logic-device (CPLD) IC chip comprising the field-programmable or configurable circuits as mentioned above.

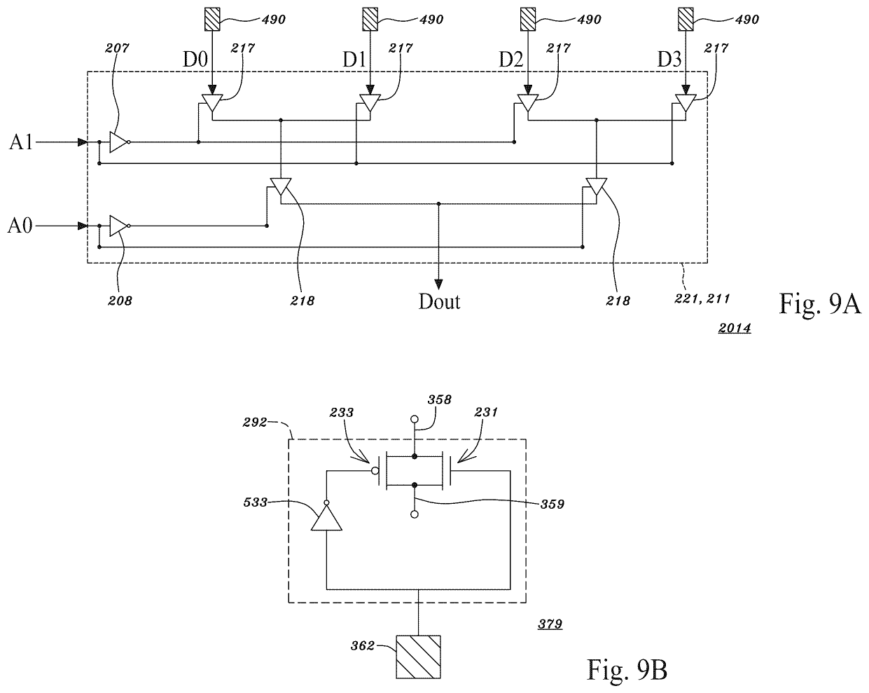

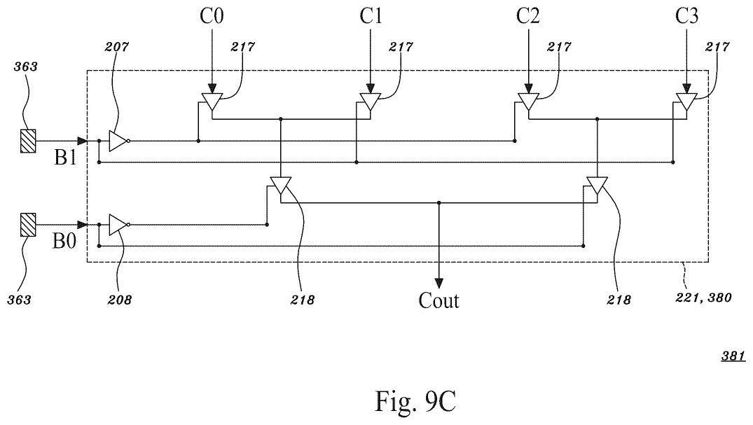

FIG. 9A is a circuit diagram illustrating a multiplexer used as the first selection circuit of the field-programmable or configurable look-up table (LUT) as seen in FIG. 8A in accordance with an embodiment of the present application. Referring to FIGS. 8A and 9A, a multiplexer 221 may have the first input data set (A0, A1) for the logic operation for the look-up table (LUT) 2014 and the second input data set (D0, D1, D2, D3) having data associated with the configuration data for the look-up table (LUT) 2014, wherein the multiplexer 221 is configured to select, in accordance with the first input data set (A0, A1) of the multiplexer 221, input data from the second input data set (DO, D1, D2, D3) of the multiplexer 221 as the output data Dout of the multiplexer 221 for the logic operation. The multiplexer 221 may include two stages of tri-state buffers 217 and 218 coupled stage by stage. For more elaboration, the multiplexer 221 may include four tri-state buffers 217 in two pairs in the first stage, i.e., input stage, arranged in parallel, each having a first data input associated with the data input A1 in the first input data set (A0, A1) of the multiplexer 221 and a second data input coupling to any of the four data inputs DO-D3 in the second input data set (DO, D1, D2, D3) of the multiplexer 221. Each of the four tri-state buffers 217 in the first stage may be switched on or off in accordance with the first data input thereof to pass or not to pass the second data input thereof to a data output thereof. The multiplexer 221 may include an inverter 207 for inverting a data input thereof coupling to the data input A1 in the first input data set (A0, A1) of the multiplexer 221 into a data output thereof. Either of the two tri-state buffers 217 in each pair of the two pairs in the first stage may be switched on in accordance with the first data input thereof coupling to one of the data input and output of the inverter 207 to pass the second data input thereof to the data output thereof; the other one of the tri-state buffers 217 in said each pair in the first stage may be switched off in accordance with the first data input thereof coupling to the other one of the data input and output of the inverter 207 not to pass the second data input thereof to the data output thereof. The data outputs of the tri-state buffers 217 in each pair of the two pairs in the first stage may couple to each other. For example, a left one of the tri-state buffers 217 in a left pair of the two pairs in the first stage may have the first data input coupling to the data output of the inverter 207 and the second data input coupling to the data input DO in the second input data set (DO, D1, D2, D3) of the multiplexer 221; a right one of the tri-state buffers 217 in the left pair of the two pairs in the first stage may have the first data input coupling to the data input of the inverter 207 and the second data input coupling to the data input D1 in the second input data set (DO, D1, D2, D3) of the multiplexer 221. The left one of the tri-state buffers 217 in the left pair of the two pairs in the first stage may be switched on in accordance with the first data input thereof to pass the second data input thereof to the data output thereof; the right one of the tri-state buffers 217 in the left pair of the two pairs in the first stage may be switched off in accordance with the first data input thereof not to pass the second data input thereof to the data output thereof. Thereby, the two tri-state buffers 217 in each pair of the two pairs in the first stage may be switched in accordance with the two first data inputs thereof coupling to the data input and output of the inverter 207 respectively to pass one of the two second data inputs thereof to one of the two data outputs thereof coupling to a second data input of one of the tri-state buffers 218 in the second stage.

Referring to FIGS. 8A and 9A, the multiplexer 221 may include two tri-state buffers 218 in the second stage, i.e., output stage, arranged in parallel, each having a first data input associated with the data input A0 in the first input data set (A0, A1) of the multiplexer 221 and a second data input coupling to the data output of a pair of the two pairs of tri-state buffers 217 in the first stage. Each of the two tri-state buffers 218 in the second stage, i.e., output stage, may be switched on or off in accordance with the first data input thereof to pass or not to pass the second data input thereof to the data output thereof. The multiplexer 221 may include an inverter 208 for inverting a data input thereof coupling to the data input A0 in the first input data set (A0, A1) of the multiplexer 221 into a data output thereof. Either of the two tri-state buffers 218 in the second stage, i.e., output stage, may be switched on in accordance with the first data input thereof coupling to one of the data input and output of the inverter 208 to pass the second data input thereof to the data output thereof; the other one of the two tri-state buffers 218 in the second stage, i.e., output stage, may be switched off in accordance with the first data input thereof coupling to the other one of the data input and output of the inverter 208 not to pass the second data input thereof to the data output thereof. The data outputs of the two tri-state buffers 218 in the second stage, i.e., output stage, may couple to each other. For example, a left one of the two tri-state buffers 218 in the second stage, i.e., output stage, may have the first data input coupling to the data output of the inverter 208 and the second data input thereof coupling to the data output of a left pair of the two pairs of tri-state buffers 217 in the first stage; a right one of the two tri-state buffers 218 in the second stage, i.e., output stage, may have the first data input coupling to the data input of the inverter 208 and the second data input coupling to the data output of a right pair of the two pairs of tri-state buffers 217 in the first stage. The left one of the two tri-state buffers 218 in the second stage, i.e., output stage, may be switched on in accordance with the first data input thereof to pass the second data input thereof to the data output thereof; the right one of the two tri-state buffers 218 in the second stage, i.e., output stage, may be switched off in accordance with the first data input thereof not to pass the second data input thereof to the data output thereof. Thereby, the two tri-state buffers 218 in the second stage, i.e., output stage, may be switched in accordance with the two first data inputs thereof coupling to the data input and output of the inverter 208 respectively to pass one of the two second data inputs thereof to one of the data outputs thereof acting as the data output Dout of the multiplexer 221.

FIG. 9B is a circuit diagram illustrating the pass/no-pass switch of the field-programmable or configurable switch as seen in FIG. 8B in accordance with an embodiment of the present application. Referring to FIGS. 8B and 9B, the pass/no-pass switch 292 of the field-programmable or configurable switch 379 may include an N-type metal-oxide-semiconductor (MOS) transistor 231, a P-type metal-oxide-semiconductor (MOS) transistor 233 coupling in parallel to the N-type metal-oxide-semiconductor (MOS) transistor 231 thereof and an inverter 235 for inverting a data input of the inverter 235 coupling to a gate terminal of the N-type MOS transistor 231 thereof and the second static random-access memory (SRAM) cell 362 of the field-programmable or configurable switch 379 into a data output of the inverter 235 coupling to a gate terminal of the P-type MOS transistor 233 thereof, wherein each of the N-type and P-type metal-oxide-semiconductor (MOS) transistors 231 and 233 of the pass/no-pass switch 292 of the field-programmable or configurable switch 379 may be provided with a channel having an end coupling to the first interconnect 358 and the other opposite end coupling to the second interconnect 359. Thereby, the pass/no-pass switch 292 of the field-programmable or configurable switch 379 may be controlled in accordance with the configuration data stored in the second static random-access memory (SRAM) cell 362 of the field-programmable or configurable switch 379 to switch on or off coupling between the first and second interconnects 358 and 359.

FIG. 9C is a circuit diagram illustrating a multiplexer used as the second selection circuit of the field-programmable or configurable selection circuit as seen in FIG. 8C in accordance with an embodiment of the present application. The multiplexer 221 as illustrated in FIG. 9A may be used as the second selection circuit 380 of the field-programmable or configurable selection circuit 381 as seen in FIGS. 8C and 9C. For an element indicated by the same reference number shown in FIGS. 9A and 9C, the specification of the element as seen in FIG. 9C may be referred to that of the element as illustrated in FIG. 9A. The difference therebetween is that the first and second input data set (A0, A1) and (DO, D1, D2, D3) are changed to (B0, B1) and (C0, C1, C2, C3) respectively for the second selection circuit 380 of the field-programmable or configurable selection circuit 381 as seen in FIGS. 8C and 9C, and the data output Dout is changed to Cout for the second selection circuit 380 of the field-programmable or configurable selection circuit 381 as seen in FIGS. 8C and 9C. Accordingly, the multiplexer 221 may have the first input data set (B0, B1) of the second selection circuit 380 having data associated with the configuration data stored in the third group of static random-access memory (SRAM) cells 363 of the field-programmable or configurable selection circuit 381 and the second input data set (C0, C1, C2, C3) of the second selection circuit 380, wherein the multiplexer 221 is configured to select, in accordance with the first input data set (B0, B1) of the multiplexer 221, input data from the second input data set (C0, C1, C2, C3) of the multiplexer 221 as the output data Cout of the multiplexer 221.

### Conclusion and Advantages

A person, user, or developer with an innovation and/or an application concept or idea or an aim for accelerating workload processing needs to purchase any type of the first through seventh types of field-programmable multi-chip packages 101, 102, 401, 402, 403, 501 and 502 as seen in FIGS. 1-4, 5A, 5B, 6 and 7 and develops or writes software codes or programs to load into said any type of the first through seventh types of field-programmable multi-chip packages 101, 102, 401, 402, 403, 501 and 502 to implement his/her innovation and/or application concept or idea, wherein his/her innovation and/or application (maybe abbreviated as innovation) comprises (i) innovative algorithms and/or architectures of computing, processing, learning and/or inferencing, and/or (ii) innovative and/or specific applications. The configuration software codes or programs developed or written by the person, user, or developer are used to configure the field-programmable-gate-array (FPGA) integrated-circuit (IC) chip in any of the seventh types of field-programmable multi-chip packages 101, 102, 401, 402, 403, 501 and 502, and are loaded and stored in the non-volatile memory (NVM) cells of the non-volatile memory (NVM) integrated-circuit (IC) chip or chips thereof. When the power of any of the multi-chip package 101, 102, 401, 402, 403, 501 and 502 is turned on, the configuration software codes or programs stored in the non-volatile memory (NVM) cells of the non-volatile memory (NVM) integrated-circuit (IC) chip or chips of said any of the seventh types of field-programmable multi-chip packages 101, 102, 401, 402, 403, 501 and 502 are loaded to and stored in the static random-access memory (SRAM) cells of the field-programmable-gate-array (FPGA) integrated-circuit (IC) chip thereof to the configure the field-programmable-gate-array (FPGA) integrated-circuit (IC) chip thereof. When the power of any of the multi-chip packages 101, 102, 401, 402, 403, 501 and 502 is turned off, the configuration software codes or programs stored in the static random-access memory (SRAM) cells of the field-programmable-gate-array (FPGA) integrated-circuit (IC) chip of said any of the seventh types of field-programmable multi-chip packages 101, 102, 401, 402, 403, 501 and 502 are backed up and stored in the non-volatile memory (NVM) integrated-circuit (IC) chip or chips thereof. The person, user, or developer may print a logo of a company on a top of said any type of the first through seventh types of field-programmable multi-chip packages 101, 102, 401, 402, 403, 501 and 502 and said any type of the first through fifth types of field-programmable multi-chip packages 101, 102, 401, 402, 403, 501 and 502 may be sold as an application specific integrated-circuit (ASIC), system-on-chip (SOC) or customer-owned-tooling (COT) chip. Said any type of the first through seventh types of field-programmable multi-chip packages 101, 102, 401, 402, 403, 501 and 502 may provide an opportunity to the person, user, or developer to enter into the chip market with small-volume demand and requiring frequently updating or upgrading.

The components, steps, features, benefits and advantages that have been discussed are merely illustrative. None of them, nor the discussions relating to them, are intended to limit the scope of protection in any way. Numerous other embodiments are also contemplated. These include embodiments that have fewer, additional, and/or different components, steps, features, benefits and advantages. These also include embodiments in which the components and/or steps are arranged and/or ordered differently.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain. Furthermore, unless stated otherwise, the numerical ranges provided are intended to be inclusive of the stated lower and upper values. Moreover, unless stated otherwise, all material selections and numerical values are representative of preferred embodiments and other ranges and/or materials may be used.

The scope of protection is limited solely by the claims, and such scope is intended and should be interpreted to be as broad as is consistent with the ordinary meaning of the language that is used in the claims when interpreted in light of this specification and the prosecution history that follows, and to encompass all structural and functional equivalents thereof.

What is claimed is:

1. A chip package comprising:
a ball-grid-array (BGA) substrate;
a first metal bump at a bottom of the ball-grid-array (BGA) substrate, wherein the first metal bump comprises tin;
a field programmable chip package over and coupling to the ball-grid-array (BGA) substrate, wherein the field programmable chip package comprises a field-programmable-gate-array (FPGA) integrated-circuit (IC) chip therein and a second metal bump at a bottom of the field programmable chip package and bonded to a top of the ball-grid-array (BGA) substrate; and
a memory chip package under and coupling to the ball-grid-array (BGA) substrate, wherein the memory chip package comprises a first non-volatile memory (NVM) integrated-circuit (IC) chip therein and a third metal bump at a top of the memory chip package and bonded to the bottom of the ball-grid-array (BGA) substrate.

2. The chip package of claim 1, wherein the memory chip package further comprises an interconnection substrate over and coupling to the first non-volatile memory (NVM) integrated-circuit (IC) chip under and coupling to the third metal bump.

3. The chip package of claim 2, wherein the memory chip package further comprises a first wirebonded wire coupling the first non-volatile memory (NVM) integrated-circuit (IC) chip to the interconnection substrate and a molding compound under the interconnection substrate and encapsulating the first non-volatile memory (NVM) integrated-circuit (IC) chip and first wirebonded wire.

4. The chip package of claim 3, wherein the memory chip package further comprises a second non-volatile memory (NVM) integrated-circuit (IC) chip therein having a first portion vertically under a first portion of the first non-volatile memory (NVM) integrated-circuit (IC) chip and a second portion horizontally offset from the first non-volatile memory (NVM) integrated-circuit (IC) chip, wherein the first non-volatile memory (NVM) integrated-circuit (IC) chip has a second portion horizontally offset from the second non-volatile memory (NVM) integrated-circuit (IC) chip, wherein the memory chip package further comprises a second wirebonded wire coupling the second non-volatile memory (NVM) integrated-circuit (IC) chip to the interconnection substrate and a third wirebonded wire coupling the second non-volatile memory (NVM) integrated-circuit (IC) chip to the first non-volatile memory (NVM) integrated-circuit (IC) chip, wherein the molding compound further encapsulates the second non-volatile memory (NVM) integrated-circuit (IC) chip and second and third wirebonded wires.

5. The chip package of claim 1, wherein the field programmable chip package further comprises an interconnection scheme under and coupling to the field-programmable-gate-array (FPGA) integrated-circuit (IC) chip, wherein the second metal bump is under and couples to the interconnection scheme.

6. The chip package of claim 5, wherein the field-programmable-gate-array (FPGA) integrated-circuit (IC) chip further comprises a fourth metal bump at a bottom of the field-programmable-gate-array (FPGA) integrated-circuit (IC) chip and coupling to the interconnection scheme.

7. The chip package of claim 6, wherein the field programmable chip package further comprises a sealing layer over the interconnection scheme and at a same horizontal level as the field-programmable-gate-array (FPGA) integrated-circuit (IC) chip, wherein the field-programmable-gate-array (FPGA) integrated-circuit (IC) chip further comprises a first polymer layer at the bottom of the field-programmable-gate-array (FPGA) integrated-circuit (IC) chip, in contact with a sidewall of the fourth metal bump and having a bottom surface coplanar with a bottom surface of the sealing layer, wherein the fourth metal bump comprises a first copper layer at the bottom of the field-programmable-gate-array (FPGA) integrated-circuit (IC) chip.

8. The chip package of claim 7, wherein the sealing layer comprises a molding compound.

9. The chip package of claim 7, wherein the field-programmable-gate-array (FPGA) integrated-circuit (IC) chip further comprises a metal pad at an active side of the field-programmable-gate-array (FPGA) integrated-circuit (IC) chip and a second polymer layer at the active side of the field-programmable-gate-array (FPGA) integrated-circuit (IC) chip, wherein the first polymer layer is on a bottom surface of the second polymer layer and the fourth metal bump has a first portion in an opening in the second polymer layer and in contact with a bottom surface of the metal pad and a second portion under the opening in the second polymer layer and on a bottom surface of the second polymer layer.

10. The chip package of claim 9, wherein the metal pad comprises an aluminum layer.

11. The chip package of claim 9, wherein the metal pad comprises a second copper layer.

12. The chip package of claim 7, wherein the interconnection scheme comprises a first interconnection metal layer under the field-programmable-gate-array (FPGA) integrated-circuit (IC) chip and sealing layer and a second interconnection metal layer under the first interconnection metal layer and an insulating dielectric layer between the first and second interconnection metal layers, wherein the first interconnection metal layer comprises a second copper layer and an adhesion metal layer at a top of the second copper layer but not at a sidewall of the second copper layer, wherein the adhesion metal layer is in contact with a bottom surface of the first copper layer.

13. The chip package further comprising an interconnection substrate under the ball-grid-array (BGA) substrate and a fourth metal bump at a bottom of the interconnection substrate, wherein the first metal bump is bonded to a top of the interconnection substrate.

14. The chip package of claim 13, wherein the memory chip package has a portion in a hole vertically in the interconnection substrate.

15. The chip package of claim 1, wherein the second metal bump comprises a copper layer having a thickness between 5 and 40 micrometers.

16. The chip package of claim 15, wherein the second metal bump further comprises a tin-containing cap under the copper layer and bonded to the top of the ball-grid-array (BGA) substrate.

17. The chip package of claim 1, wherein the first non-volatile memory (NVM) integrated-circuit (IC) chip is a NAND flash chip.

18. The chip package of claim 1, wherein the first non-volatile memory (NVM) integrated-circuit (IC) chip is a NOR flash chip.

19. The chip package of claim 1, wherein the field-programmable-gate-array (FPGA) integrated-circuit (IC) chip comprises a memory cell for storing therein first data loaded from the first non-volatile memory (NVM) integrated-circuit (IC) chip, a first and a second interconnect and a switch having a first node coupling to the first interconnect, a second node coupling to the second interconnect and a third node coupling to the memory cell, wherein second data at the third node is associated with the first data stored in the memory cell, wherein the switch is configured for programmable interconnection by controlling, in accordance with the second data, coupling between the first and second interconnects.

20. The chip package of claim 1, wherein the field-programmable-gate-array (FPGA) integrated-circuit (IC) chip comprises a memory cell for storing therein a resulting value for a look-up table (LUT) of a logic operation and a selection circuit comprising a first set of input points for a first input data set for the logic operation and a second set of input points for a second input data set, wherein the second input data set comprises input data associated with the resulting value, wherein the selection circuit is configured to select, in accordance with the first input data set, the input data from the second input data set as output data for the logic operation, wherein the resulting value for the look-up table (LUT) of the logic operation is loaded from the first non-volatile memory (NVM) integrated-circuit (IC) chip.
